(19) United States
(12) Patent Application Publication
(10) Pub. No.: US 2025/0044701 A1
(43) Pub. Date: Feb. 6, 2025

(54) METHOD FOR PRODUCING SEMICONDUCTOR SUBSTRATE AND SILICON-CONTAINING COMPOSITION

(71) Applicant: JSR CORPORATION, Tokyo (JP)

(72) Inventors: Kazunori SAKAI, Tokyo (JP); Tatsuya KASAI, Tokyo (JP); Ayaka SUZUKI, Tokyo (JP); Akitaka NII, Tokyo (JP)

(73) Assignee: JSR CORPORATION, Tokyo (JP)

(21) Appl. No.: 18/919,818

(22) Filed: Oct. 18, 2024

Related U.S. Application Data
(63) Continuation-in-part of application No. PCT/JP2023/014519, filed on Apr. 10, 2023.

(30) Foreign Application Priority Data
Apr. 22, 2022 (JP) 2022-070663

(51) Int. Cl. G03F 7/00; C08K 5/5419; C09D 133/06; G03F 7/039; G03F 7/075; G03F 7/16; H01L 21/027

(52) U.S. Cl. CPC G03F 7/70033; C09D 133/06; G03F 7/039; G03F 7/0755; G03F 7/162; C08K 5/5419; H01L 21/0274

(57) ABSTRACT

A method for producing a semiconductor substrate includes: applying a silicon-containing composition directly or indirectly to a substrate to form a silicon-containing film; applying a composition for forming a resist film to the silicon-containing film to form a resist film; exposing the resist film to radiation; and developing at least the exposed resist film. The silicon-containing composition includes: a silicon-containing compound; a polymer including a structural unit represented by formula (1); and a solvent. A content of the silicon-containing compound in the silicon-containing composition relative to 100% by mass of components other than the solvent in the silicon-containing composition is from 50% to 99.9% by mass. R^{A1} is a hydrogen atom or a monovalent organic group having 1 to 20 carbon atoms; and R^{A2} is a monovalent organic group having 1 to 20 carbon atoms.

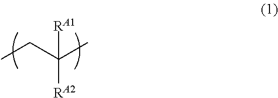

### CROSS-REFERENCE TO RELATED APPLICATIONS

The present application is a continuation-in-part application of International Patent Application No. PCT/JP2023/014519 filed Apr. 10, 2023, which claims priority to Japanese Patent Application No. 2022-070663 filed Apr. 22, 2022. The contents of these applications are incorporated herein by reference in their entirety.

### BACKGROUND OF THE DISCLOSURE

### Technical Field

The present disclosure relates to a method for producing a semiconductor substrate, and a silicon-containing composition.

### Background Art

For pattern formation in the manufacture of semiconductor substrates, for example, a multilayer resist process or the like is used in which a patterned substrate is formed by etching using, as a mask, a resist pattern obtained by exposing and developing a resist film laminated on a substrate via an organic underlayer film, a silicon-containing film, and the like (WO2012/0393337).

### SUMMARY

According to an aspect of the present disclosure, a method for producing a semiconductor substrate includes: applying a silicon-containing composition directly or indirectly to a substrate to form a silicon-containing film; applying a composition for forming a resist film to the silicon-containing film to form a resist film; exposing the resist film to radiation; and developing at least the exposed resist film. The silicon-containing composition includes: a silicon-containing compound (hereinafter also referred to as a “compound [A]”); a polymer including a structural unit represented by formula (1) (hereinafter also referred to as a “polymer [B]”); and a solvent (hereinafter also referred to as a “solvent [C]”). A content of the silicon-containing compound in the silicon-containing composition relative to 100% by mass of components other than the solvent in the silicon-containing composition is from 50% to 99.9% by mass. R^{A1} is a hydrogen atom or a monovalent organic group having 1 to 20 carbon atoms; and R^{A2} is a monovalent organic group having 1 to 20 carbon atoms.

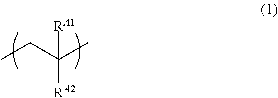

According to another aspect of the present disclosure, a silicon-containing composition for forming a resist underlayer film includes: a silicon-containing compound; a polymer including a structural unit represented by formula (1); and a solvent. A content of the silicon-containing compound in the silicon-containing composition relative to 100% by mass of components other than the solvent in the silicon-containing composition is from 50% to 99.9% by mass.

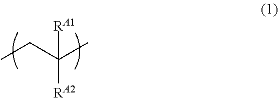

In the formula (1), R^{A1} is a hydrogen atom or a monovalent organic group having 1 to 20 carbon atoms; and R^{A2} is a monovalent organic group having 1 to 20 carbon atoms.

### DETAILED DESCRIPTION OF THE PREFERRED EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In the present disclosure, the term “organic group” refers to a group containing at least one carbon atom, and the term “carbon number” refers to the number of carbon atoms that make up the group.

In recent years, the level of integration of semiconductor devices has been increased, and the light used for exposure is shifting to shorter wavelength, from KrF excimer lasers (248 nm) and ArF excimer lasers (193 nm) to extreme ultraviolet (13.5 nm, also referred to as “EUV”).

As the line width of resist patterns formed by exposure and development of extreme ultraviolet is being reduced to a level of 20 nm or less, silicon-containing films are required to have both the ability to suppress collapse of resist patterns and uniform film thickness.

The manufacturing method for the semiconductor substrate of the present embodiment forms a silicon-containing film that is excellent in both resist pattern collapse suppression and film thickness uniformity, so it is possible to efficiently manufacture high-quality semiconductor substrates.

The silicon-containing composition of the present embodiment can form a silicon-containing film that is excellent in both resist pattern collapse suppression and film thickness uniformity. Therefore, they can be used suitably for the manufacture of semiconductor devices, etc., which are expected to become even more miniaturized in the future.

Hereinafter, a method for producing a semiconductor substrate and a silicon-containing composition according to embodiments of the present disclosure will be described in detail. Combinations of suitable modes in the embodiments are also preferred.

### <<Method for Producing Semiconductor Substrate>>

The method for producing a semiconductor substrate according to the present embodiment includes applying a silicon-containing composition directly or indirectly to a substrate (this step is hereinafter also referred to as “application step (I)”); applying a composition for forming a resist film to the silicon-containing film formed by applying the silicon-containing composition (this step is hereinafter also referred to as “application step (II)”); exposing the resist film formed by applying the composition for forming a resist film to radiation (this step is hereinafter also referred to as “exposure step”); and developing at least the exposed resist film (this step is hereinafter also referred to as “development step”).

The method for producing a semiconductor substrate may further include, if necessary, forming an organic underlayer film directly or indirectly on the substrate (hereinafter, also referred to as an “organic underlayer film forming step”) before the application step (I).

Further, the method for producing a semiconductor substrate may further include, after the developing step, etching the silicon-containing film using the resist pattern as a mask to form a silicon-containing film pattern (hereinafter, also referred to as a “silicon-containing film pattern forming step”), performing etching using the silicon-containing film pattern as a mask (hereinafter, also referred to as an “etching step”), and removing the silicon-containing film pattern by a basic liquid (hereinafter, also referred to as a “removing step”).

Hereinafter, the silicon-containing composition to be used in the method for producing a semiconductor substrate, and the respective steps in the case of including the organic underlayer film forming step, which is an optional step, will be described.

### <<Silicon-Containing Composition>>

The silicon-containing composition is suitable for forming a resist underlayer film, and includes a compound [A], a polymer [B], and a solvent [C]. The silicon-containing composition may further include other optional components as long as the effects of the present invention are not impaired.

### <Compound [A]>

The compound [A] is a compound containing a silicon atom. The compound [A] is not particularly limited as long as it contains a silicon atom, but is preferably at least one of polysiloxane and polycarbosilane. The silicon-containing composition may include one type or two or more types of the compound [A].

### (Polysiloxane)

When the compound [A] is polysiloxane, the compound [A] preferably has a structural unit represented by formula (2-1) (hereinafter also referred to as “structural unit (2-1)”). The compound [A] may contain one type or two or more types of the structural units (2-1).

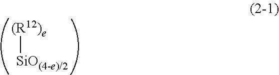

in the formula (2-1), R¹² is a monovalent organic group having 1 to 20 carbon atoms, a hydroxy group, or a halogen atom; e is an integer of 0 to 3, and when e is 2 or more, the plurality of R¹²s are identical or different.

Examples of the monovalent organic group having 1 to 20 carbon atoms represented by R¹² include:
a monovalent hydrocarbon group having 1 to 20 carbon atoms;
a group containing a divalent hetero atom-containing liking group between two adjacent carbon atoms or at the end of the hydrocarbon group (hereinafter, also referred to as a “group (α)”);
a group obtained by substituting some or all of the hydrogen atoms of the hydrocarbon group or the group (α) with a monovalent hetero atom-containing substituent (hereinafter, also referred to as a “group (β)”); and
a group obtained by combining the hydrocarbon group, the group (α) or the group (β) with a divalent hetero atom-containing linking group (hereinafter, also referred to as a “group (γ)”).

As used herein, the “hydrocarbon group” includes a chain hydrocarbon group, an alicyclic hydrocarbon group, and an aromatic hydrocarbon group. The “hydrocarbon group” may be a saturated hydrocarbon group or an unsaturated hydrocarbon group. The “chain hydrocarbon group” means a hydrocarbon group that does not include a cyclic structure and is composed only of a chain structure, and includes both a linear hydrocarbon group and a branched hydrocarbon group. The “alicyclic hydrocarbon group” means a hydrocarbon group that includes only an alicyclic structure as a ring structure and does not include an aromatic ring structure, and includes both a monocyclic alicyclic hydrocarbon group and a polycyclic alicyclic hydrocarbon group. However, it is not necessary for the alicyclic hydrocarbon group to be composed only of an alicyclic structure, and the alicyclic hydrocarbon group may include a chain structure in a part thereof. The “aromatic hydrocarbon group” means a hydrocarbon group that includes an aromatic ring structure as a ring structure. However, it is not necessary for the aromatic hydrocarbon group to be composed only of an aromatic ring structure, and the aromatic hydrocarbon group may include a chain structure or an alicyclic structure in a part thereof.

Examples of the monovalent hydrocarbon group having 1 to 20 carbon atoms include monovalent chain hydrocarbon groups having 1 to 20 carbon atoms, monovalent alicyclic hydrocarbon groups having 3 to 20 carbon atoms, monovalent aromatic hydrocarbon groups having 6 to 20 carbon atoms or a combination of these groups.

Examples of monovalent chain hydrocarbon groups having 1 to 20 carbon atoms include alkyl groups such as a methyl group, an ethyl group, a n-propyl group, an i-propyl group, a n-butyl group, a sec-butyl group, an iso-butyl group, a tert-butyl group, alkenyl groups such as an ethenyl group, a propenyl group and a butenyl group, and alkynyl groups such as an ethynyl group, a propynyl group and a butynyl group.

Examples of monovalent alicyclic hydrocarbon groups having 3 to 20 carbon atoms include monocyclic saturated alicyclic hydrocarbon groups such as cyclopentyl group and cyclohexyl group, polycyclic alicyclic saturated hydrocarbon groups such as a norbornyl group, an adamantyl group, a tricyclodecyl group, a tetracyclododecyl group, monocyclic alicyclic unsaturated hydrocarbon groups such as a cyclopentenyl group and a cyclohexenyl group, polycyclic alicyclic unsaturated hydrocarbon groups such as a norbornenyl group, a tricyclodecenyl group, a tetracyclododesenyl group.

Examples of monovalent aromatic hydrocarbon groups having 6 to 20 carbon atoms include aryl groups such as a phenyl group, a tolyl group, a xylyl group, a naphthyl group and an anthryl group, aralkyl groups such as a benzyl group, a phenethyl group, a naphthylmethyl group and an anthrylmethyl group.

Examples of the heteroatoms that constitute the divalent heteroatom-containing linking group and the monovalent heteroatom-containing substituent include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom. (In this specification, unless otherwise specified, the term “halogen atom” includes these atoms.)

Examples of the divalent heteroatom-containing liking groups include, for example, —O—, —C(═O)—, —S—, —C(═S)—, —NR′—, —SO₂—, or combinations of two or more of these and the like. R′ is a hydrogen atom or a monovalent hydrocarbon group.

Examples of the monovalent hetero atom-containing substituent include a halogen atom, a hydroxy group, a carboxy group, a cyano group, an amino group, and a sulfanyl group.

R¹² is preferably a substituted or unsubstituted monovalent alkoxy group having 1 to 20 carbon atoms, a substituted or unsubstituted aryl group having 6 to 20 carbon atoms, or a substituted or unsubstituted alkyl group having 1 to 10 carbon atoms.

Examples of the monovalent alkoxy group having 1 to 20 carbon atoms include alkoxy groups such as a methoxy group, an ethoxy group, an n-propoxy group, and an isopropoxy group.

Examples of the aryl group having 6 to 20 carbon atoms include a phenyl group, a naphthyl group, and an anthracenyl group.

Examples of the alkyl group having 1 to 10 carbon atoms include a methyl group, an ethyl group, an n-propyl group, an i-propyl group, a n-butyl group, an i-butyl group, and a t-butyl group.

When the alkoxy group, the aryl group, and the alkyl group have a substituent, the monovalent hetero atom-containing substituent described above can be suitably employed as the substituent. Further, examples of the substituent of the aryl group include an alkyl group, an alkoxy group, an alkoxycarbonyl group, an alkoxycarbonyloxy group, an acyl group, an acyloxy group, and a group obtained by substituting a hydrogen atom of these groups with a halogen atom.

e is preferably an integer of 0 to 2, and more preferably 0 or 1. The polysiloxane as the compound [A] preferably has, as the structural unit (2-1), a structural unit in which e in the formula (2-1) is 0 (hereinafter also referred to as a “structural unit (2-1-e0)”) and a structural unit in which e is 1 (hereinafter also referred to as a “structural unit (2-1-el)”) in combination.

Examples of the structural unit (2-1) include structural units derived from the compounds represented by formulas (2-1-1) to (2-1-12) (hereinafter also referred to as “structural units (2-1-1) to (2-1-12)”).

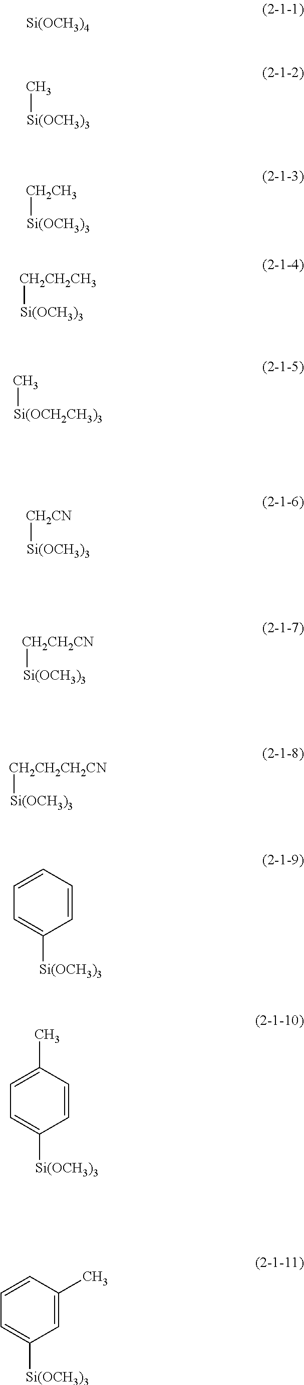

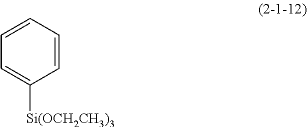

When the polysiloxane has the structural unit (2-1-e0), the lower limit of the content ratio of the structural unit (2-1-e0) accounting for among all structural units constituting the polysiloxane is preferably 30 mol %, more preferably 40 mol %, and still more preferably 45 mol %. The upper limit of the content ratio of the structural unit (2-1-e0) may be 100 mol %, and is preferably 96 mol %, and more preferably 92 mol %.

When the polysiloxane has the structural unit (2-1-el), the lower limit of the content ratio of the structural unit (2-1-el) accounting for among all structural units constituting the polysiloxane is preferably 1 mol %, more preferably 5 mol %, and still more preferably 8 mol %. The upper limit of the content ratio of the structural unit (2-1-el) is preferably 80 mol %, more preferably 70 mol %, and still more preferably 60 mol %.

### (Polycarbosilane)

When the compound [A] is polycarbosilane, the compound [A] preferably has a structural unit represented by formula (3-1) (hereinafter also referred to as “structural unit (3-1)”). The compound [A] may contain one type or two or more types of the structural units (3-1).

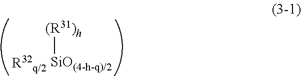

in the formula (3-1), R³¹ is a monovalent organic group having 1 to 20 carbon atoms, a hydroxy group, a hydrogen atom, or a halogen atom; h is 1 or 2; when h is 2, two R³¹s are identical or different from each other; R³² is a substituted or unsubstituted divalent hydrocarbon group having 1 to 20 carbon atoms and bonded to two silicon atoms; q is an integer of 1 to 3; when q is 2 or more, the plurality of R³²s are identical or different from each other; and h+q is 4 or less.

As the monovalent organic group having 1 to 20 carbon atoms represented by R³¹, a monovalent organic group having 1 to 20 carbon atoms represented by R¹² of the above formula (2-1) can be suitably employed.

R³¹ is preferably a hydrogen atom, a monovalent chain hydrocarbon group, a monovalent aromatic hydrocarbon group, or a monovalent group in which some or all of the hydrogen atoms of the monovalent hydrocarbon group are replaced with a monovalent hetero atom-containing group, more preferably a hydrogen atom, an alkyl group or an aryl group, and further preferably a hydrogen atom, a methyl group, an ethyl group, or a phenyl group.

Examples of the substituted or unsubstituted divalent hydrocarbon group having 1 to 20 carbon atoms and bonded to two silicon atoms represented by R³² include a substituted or unsubstituted divalent chain hydrocarbon group having 1 to 20 carbon atoms, a substituted or unsubstituted divalent aliphatic cyclic hydrocarbon group having 3 to 20 carbon atoms, and a substituted or unsubstituted divalent aromatic hydrocarbon group having 6 to 20 carbon atoms.

Examples of the unsubstituted divalent chain hydrocarbon group having 1 to 20 carbon atoms include chain saturated hydrocarbon groups such as a methanediyl group and an ethanediyl group, and chain unsaturated hydrocarbon groups such as an ethenediyl group and a propenediyl group.

Examples of the unsubstituted divalent aliphatic cyclic hydrocarbon group having 3 to 20 carbon atoms include monocyclic saturated hydrocarbon groups such as a cyclobutanediyl group, monocyclic unsaturated hydrocarbon groups such as a cyclobutenediyl group, polycyclic saturated hydrocarbon groups such as a bicyclo[2.2.1]heptanediyl group, and polycyclic unsaturated hydrocarbon groups such as a bicyclo[2.2.1]heptenediyl group.

Examples of the unsubstituted divalent aromatic hydrocarbon group having 6 to 20 carbon atoms include a phenylene group, a biphenylene group, a phenylene ethylene group, and a naphthylene group.

Examples of the substituent in the substituted divalent hydrocarbon group having 1 to 20 carbon atoms represented by R³² include a halogen atom, a hydroxy group, a cyano group, a nitro group, an alkoxy group, an acyl group, and an acyloxy group.

As R³², an unsubstituted chain saturated hydrocarbon group or an unsubstituted aromatic hydrocarbon group is preferable, and a methanediyl group, an ethanediyl group, or a phenylene group is more preferable.

h is preferably 1.

q is preferably 2 or 3.

The polycarbosilane as the compound [A] preferably has, as the structural unit (3-1), a structural unit in which R³¹ in the formula (3-1) is a hydrogen atom (hereinafter also referred to as “structural unit (3-1-a)”), and a structural unit in which R³¹ is a monovalent group in which some or all of the hydrogen atoms of a monovalent chain hydrocarbon group, a monovalent aromatic hydrocarbon group, or a monovalent hydrocarbon group are substituted with a monovalent hetero atom-containing group (hereinafter also referred to as “structural unit (3-1-b)”) in combination.

Examples of the structural unit (3-1) include a structural unit derived from a combination of a compound represented by formula (3-1-1) and one or more among the compounds represented by formulas (3-1-2) to (3-1-6).

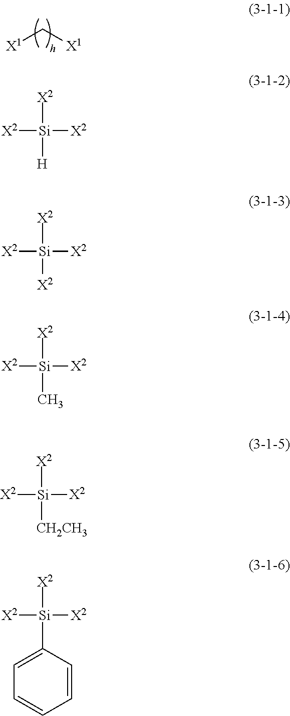

in the formulas (3-1-1) to (3-1-6), X¹ and X² are each independently a halogen atom; and h is an integer of 1 to 5.

When the polycarbosilane has the structural unit (3-1-a), the lower limit of the content ratio of the structural unit (3-1-a) accounting for among all structural units constituting the polycarbosilane is preferably 10 mol %, more preferably 15 mol %, and still more preferably 20 mol %. The upper limit of the content ratio of the structural unit (3-1-a) may be 70 mol %, and is preferably 60 mol %, and more preferably 50 mol %.

When the polycarbosilane has the structural unit (3-1-b), the lower limit of the content ratio of the structural unit (3-1-b) accounting for among all structural units constituting the polycarbosilane is preferably 5 mol %, more preferably 8 mol %, and still more preferably 12 mol %. The upper limit of the content ratio of the structural unit (3-1-b) is preferably 50 mol %, more preferably 40 mol %, and still more preferably 30 mol %.

The lower limit of the content ratio of the compound [A] is preferably 0.05% by mass, more preferably 0.1% by mass, still more preferably 0.3% by mass, and particularly preferably 0.6% by mass, based on all the components of the silicon-containing composition. The upper limit of the content ratio is preferably 10% by mass, more preferably 8% by mass, still more preferably 5% by mass, and particularly preferably 3% by mass.

The compound [A] is preferably in the form of a polymer. The term “polymer” refers to a compound having two or more structural units, and when two or more identical structural units are consecutive in a polymer, the structural units are also referred to as “structural units”. When the compound [A] is in the form of a polymer, the lower limit of the polystyrene-equivalent weight-average molecular weight (Mw) of the compound [A] determined by gel permeation chromatography (GPC) is preferably 800, more preferably 1,000, still more preferably 1,300, and particularly preferably 1,500. The upper limit of Mw is preferably 10,000, more preferably 8,000, still more preferably 6,000, and particularly preferably 4,000. The Mw of the compound [A] is measured as described in Examples.

### <Synthesis of Compound [A]>

When the compound [A] is polysiloxane, the polysiloxane is obtained, for example, by hydrolysis condensation or the like of one or more silane compounds that afford the structural unit (2-1). When the compound [A] is polycarbosilane, the polycarbosilane is obtained, for example, by hydrolysis condensation of polycarbosilane having one or two or more structural units (3-1) or hydrolysis condensation of polycarbosilane having one or two or more structural units (3-1) and one or two or more silane compounds that afford the structural unit (3-1). At the time of any of the hydrolysis condensations, another silane compound or the like may be added, as necessary. The hydrolysis condensation can be performed by performing hydrolysis condensation in a solvent such as diisopropyl ether in the presence of water and a catalyst such as oxalic acid, and preferably purifying a solution containing the generated hydrolysis condensate through solvent substitution or the like in the presence of a dehydrating agent such as ortho ester or molecular sieve. It is considered that each hydrolyzable silane monomer is incorporated into the compound [A] through a hydrolysis condensation reaction or the like regardless of the type of the hydrolyzable silane monomer. The content ratio of the structural unit (2-1), the structural unit (3-1), and other structural units in the compound [A] synthesized is usually equivalent to the ratio of the amounts of the respective monomer compounds used in the synthesis reaction.

### <Polymer [B]>

The polymer [B] has a structural unit represented by formula (1),

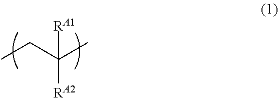

in the formula (1), R^{A1} is a hydrogen atom or a monovalent organic group having 1 to 20 carbon atoms; and R^{A2} is a monovalent organic group having 1 to 20 carbon atoms.

As the monovalent organic group having 1 to 20 carbon atoms represented by R^{A1} and R^{A2}, a monovalent organic group having 1 to 20 carbon atoms represented by R¹² of the above formula (2-1) can be suitably employed. R^{A1} and R^{A2} are preferably different from each other.

The polymer [B] preferably has at least one type of structural unit selected from a structural unit represented by formula (1-1) (hereinafter also referred to as “structural unit (1-1)”) and a structural unit represented by formula (1-2) (excluding the case of being a structural unit represented by formula (1-1); hereinafter also referred to as “structural unit (1-2)”)). The polymer [B] may have one type or two or more types of the structural unit (1-1) and one type or two or more types of the structural unit (1-2).

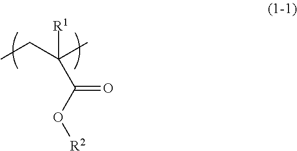

in the formula (1-1), R¹ is a hydrogen atom or a substituted or unsubstituted monovalent organic group having 1 to 20 carbon atoms; and R² is a monovalent organic group having 1 to 20 carbon atoms.

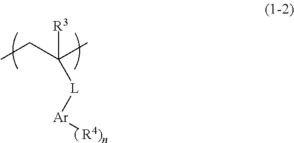

in the formula (1-2), R³ is a hydrogen atom or a substituted or unsubstituted monovalent hydrocarbon group having 1 to 20 carbon atoms; L is a single bond or a divalent linking group; Ar is a group obtained by removing (n+1) hydrogen atoms from a substituted or unsubstituted aromatic ring having 6 to 20 ring members; R⁴ is a monovalent organic group having 1 to 20 carbon atoms or a hydroxy group; n is an integer of 0 to 8; and when n is 2 or more, the plurality of R⁴s are identical or different.

In the formula (1-1), as the monovalent organic group having 1 to 20 carbon atoms represented by R¹ and R², a monovalent organic group having 1 to 20 carbon atoms represented by R¹² of the above formula (2-1) can be suitably employed. When R² is a monovalent organic group having 4 to 20 carbon atoms, R¹ is preferably a hydrogen atom or a methyl group. When R² is a monovalent organic group having 1 to 3 carbon atoms, R¹ is preferably a group having a carbonyl group, an oxygen atom (—O—), an imino group (—NH—), or a combination thereof between two adjacent carbon atoms of a monovalent hydrocarbon group. Some or all of the hydrogen atoms of the monovalent hydrocarbon group in R¹ in this case are preferably substituted with at least one among halogen atoms and a hydroxy group. The halogen atom as the substituent of R¹ is preferably a fluorine atom.

The monovalent organic group having 1 to 20 carbon atoms represented by R² is preferably a substituted or unsubstituted monovalent hydrocarbon group having 1 to 20 carbon atoms. As the monovalent hydrocarbon group having 1 to 20 carbon atoms, the groups disclosed as the monovalent hydrocarbon groups having 1 to 20 carbon atoms in R¹² of the formula (2-1) can be suitably employed. R² is preferably a monovalent chain hydrocarbon group having 1 to 15 carbon atoms or an alicyclic hydrocarbon group having 3 to 12 carbon atoms. When R² is an alicyclic hydrocarbon group having 3 to 12 carbon atoms, a monovalent chain hydrocarbon group having 1 to 5 carbon atoms is preferably bonded to the carbon atom bonded to an oxygen atom in the formula (1-1). When R² has a substituent, examples of the substituent suitably include the substituents disclosed when R¹² in the formula (1) is a substituted or unsubstituted aryl group having 6 to 20 carbon atoms.

Examples of the structural unit (1-1) include structural units represented by formulas (1-1-1) to (1-1-28).

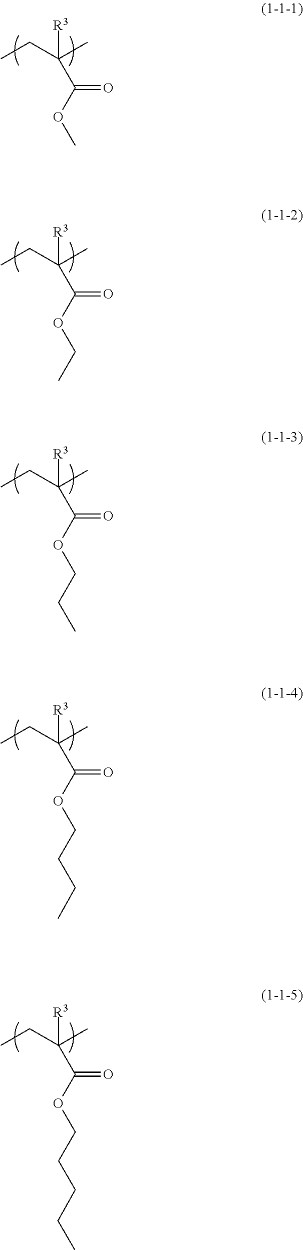

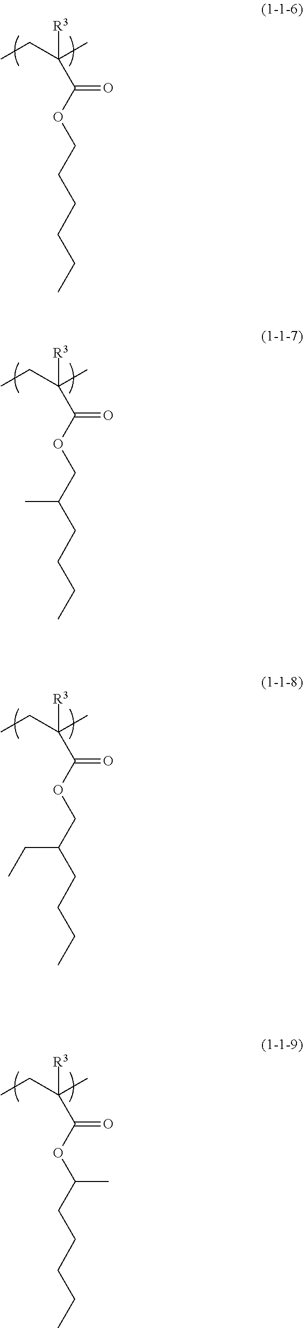

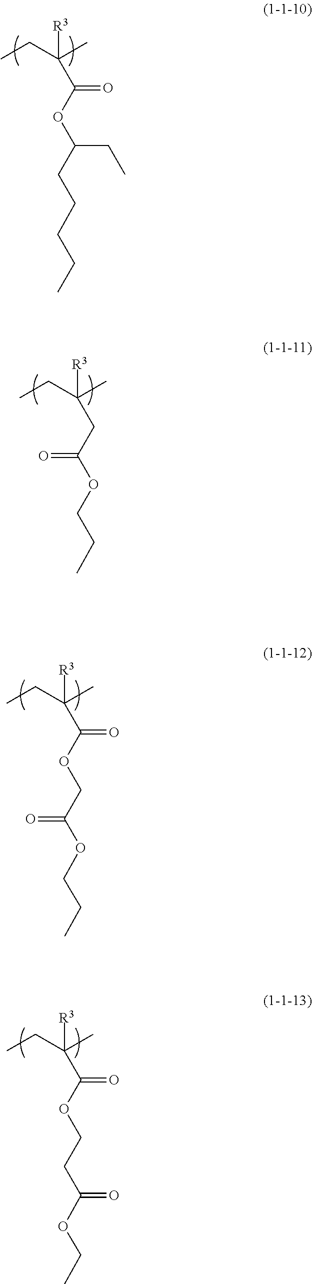

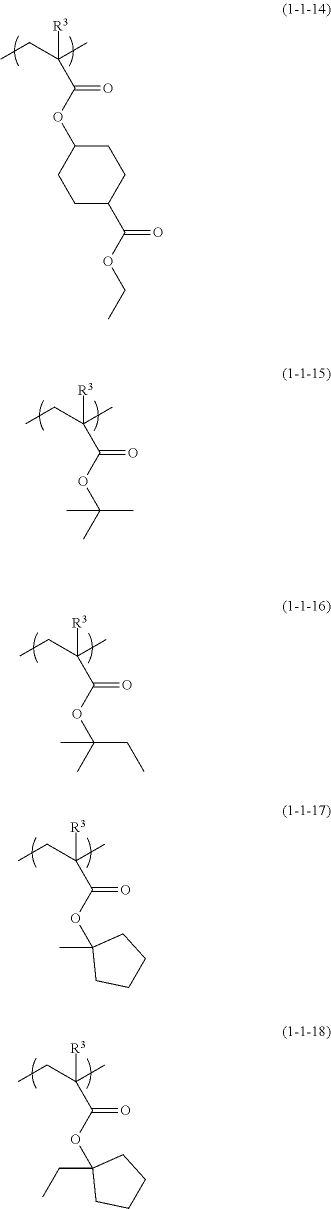

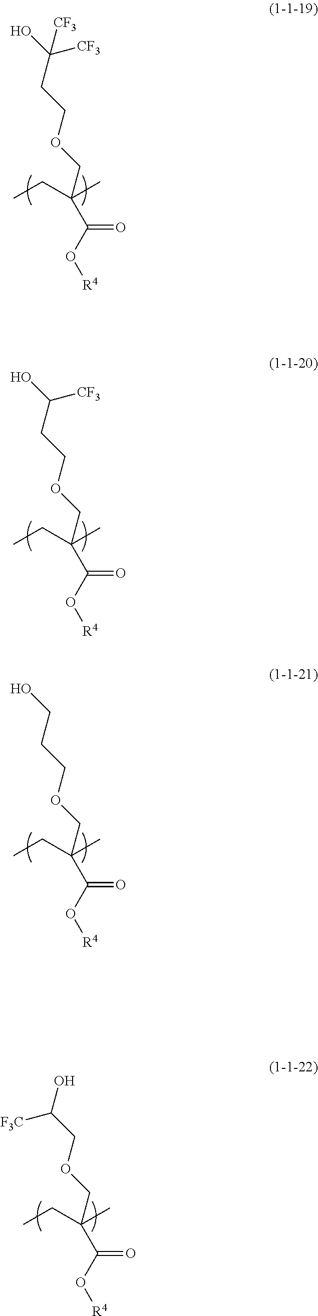

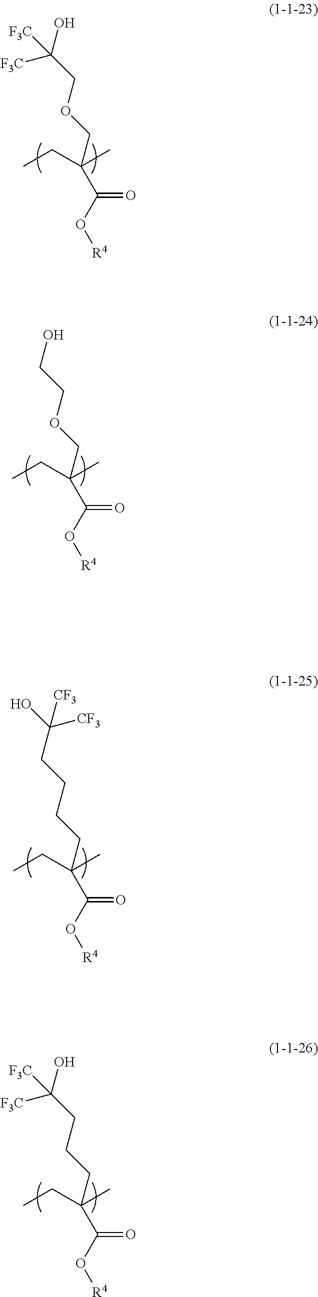

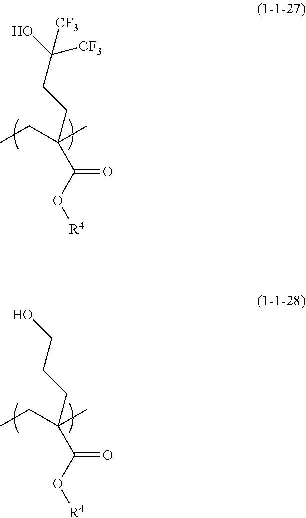

In the above formulas (1-1-1) to (1-1-18), R³ is a hydrogen atom or a methyl group, and in the formulas (1-1-19) to (1-1-28), R⁴ is a monovalent hydrocarbon group having 1 to 3 carbon atoms.

The polymer [B] may be a homopolymer having only the structural unit (1-1). In this case, the content ratio of the structural unit (1-1) is 100 mol %. When the polymer [B] is a copolymer having the structural unit (1-1) and other structural units, the lower limit of the content ratio of the structural unit (1-1) accounting for among all structural units constituting the polymer [B] is preferably 5 mol %, more preferably 10 mol %, and still more preferably 12 mol %. The upper limit of the content is preferably 80 mol %, more preferably 70 mol %, and still more preferably 60 mol %.

In the formula (1-2), as the substituted or unsubstituted monovalent hydrocarbon group having 1 to 20 carbon atoms represented by R³, the groups disclosed as the substituted or unsubstituted monovalent hydrocarbon group having 1 to 20 carbon atoms as R² of the formula (1-1) can be suitably employed. R³ is preferably a hydrogen atom or a methyl group in terms of copolymerizability of a monomer that affords the structural unit (1-2).

In the formula (1-2), examples of the divalent linking group represented by L include divalent hydrocarbon groups having 1 to 10 carbon atoms, —COO—, —CO—, —O—, —CONH—, and combinations thereof. As L, a single bond, an alkanediyl group obtained by removing one hydrogen atom from an alkyl group having 1 to 10 carbon atoms, a cycloalkylene group obtained by removing one hydrogen atom from a cycloalkyl group having 5 to 10 carbon atoms, a carbonyl group, an oxygen atom, or a combination thereof is a preferable, a single bond, an alkanediyl group having 1 to 5 carbon atoms, a cycloalkylene group having 5 to 7 carbon atoms, a carbonyl group, an oxygen atom, or a combination thereof is more preferable, and a single bond is still more preferable.

In the formula (1-2), examples of the aromatic ring having 6 to 20 ring members as Ar include aromatic hydrocarbon rings such as a benzene ring, a naphthalene ring, an anthracene ring, an indene ring, and a pyrene ring, aromatic heterocyclic rings such as a pyridine ring, a pyrazine ring, a pyrimidine ring, a pyridazine ring, and a triazine ring, or a combination thereof. The aromatic ring of the Ar is preferably at least one aromatic hydrocarbon ring selected from the group consisting of a benzene ring, a naphthalene ring, an anthracene ring, a phenalene ring, a phenanthrene ring, a pyrene ring, a fluorene ring, a perylene ring, and a coronene ring, and more preferably a benzene ring, a naphthalene ring, or a pyrene ring. In the present specification, the term “ring members” refers to the number of the atoms constituting the ring, and in the case of a polycyclic ring, it refers to the number of the atoms constituting the polycyclic ring. For example, a biphenyl ring has 12 ring members, a naphthalene ring has 10 ring members, and a fluorene ring has 13 ring members.

Examples of the substituent in Ar include the same groups as those disclosed as examples of the substituent in R² of the above formula (1-1). However, R⁴ described later is not regarded as a substituent in Ar.

As Ar, a group obtained by removing (n+1) hydrogen atoms from an unsaturated aromatic ring having 6 to 20 ring members is preferable, a group obtained by removing (n+1) hydrogen atoms from an unsaturated aromatic hydrocarbon ring having 6 to 20 ring members is more preferable, and a group obtained by removing (n+1) hydrogen atoms from an unsubstituted benzene ring is still more preferable.

R⁴ is preferably a monovalent hydrocarbon group having 1 to 20 carbon atoms that has a hydroxy group, or a hydroxy group. As the monovalent hydrocarbon group having 1 to 20 carbon atoms that has a hydroxy group represented by R⁴, the groups disclosed as the monovalent hydrocarbon group having 1 to 20 carbon atoms as R² in the above formula (1-1) can be suitably employed. R⁴ is preferably a monovalent hydroxyalkyl group having 1 to 10 carbon atoms or a hydroxy group. The hydroxyalkyl group is a group in which some or all of the hydrogen atoms of a monovalent alkyl group having 1 to 10 carbon atoms are substituted with hydroxy groups.

As the monovalent hydroxyalkyl group having 1 to 10 carbon atoms represented by R⁴, a monovalent monohydroxyalkyl group having 1 to 10 carbon atoms is more preferable, and a monohydroxymethyl group is still more preferable. R⁴ is preferably a monovalent monohydroxyalkyl group having 1 to 5 carbon atoms or a hydroxy group, and more preferably a hydroxymethyl group, a hydroxyethyl group, or a hydroxy group.

n is preferably 1 to 5, more preferably 1 to 3, still more preferably 1 or 2, and particularly preferably 1.

Examples of the structural unit (1-2) include structural units represented by formulas (1-2-1) to (1-2-10).

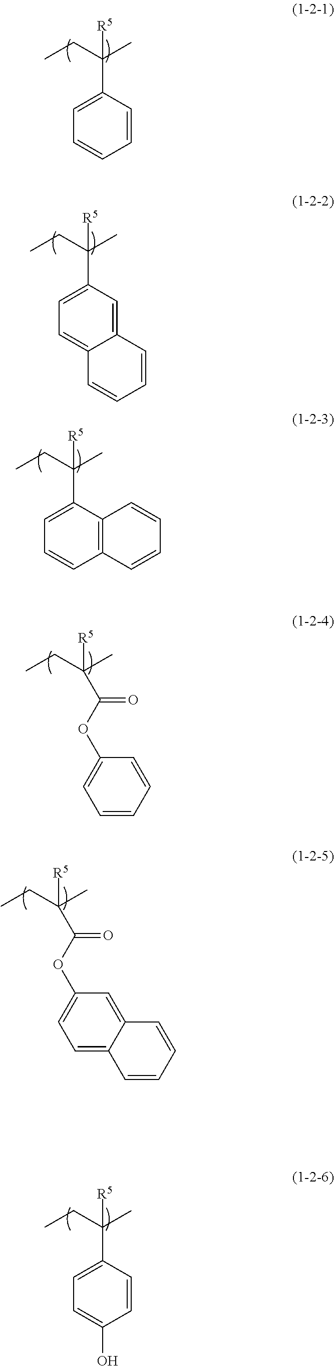

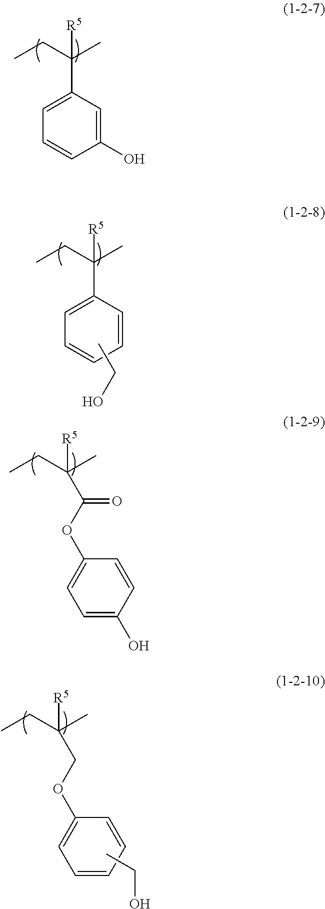

In the formulas (1-2-1) to (1-2-10), R⁵ has the same definition as that in the formula (1-2).

The polymer [B] preferably has at least a structural unit (1-2) in which n in the formula (1-2) is 1. The polymer [B] may further have a structural unit (1-2) in which n is 0.

When the polymer [B] has the structural unit (1-2), the lower limit of the content ratio of the structural unit (1-2) accounting for among all structural units constituting the polymer [B](when there are a plurality of types of the structural unit (1-2), the total content ratio is taken) is preferably 10 mol %, more preferably 20 mol %, and still more preferably 30 mol %. The upper limit of the content ratio is preferably 95 mol %, more preferably 90 mol %, and still more preferably 85 mol %.

The polymer [B] may have a structural unit containing at least one selected from the group consisting of a lactone structure, a cyclic carbonate structure, and a sultone structure (this unit is hereinafter also referred to as “structural unit (1-3)”). The polymer [B] may have one type or two or more types of the structural units (1-3).

Examples of the structural unit (1-3) include structural units represented by formulas (1-3-1) to (1-3-10).

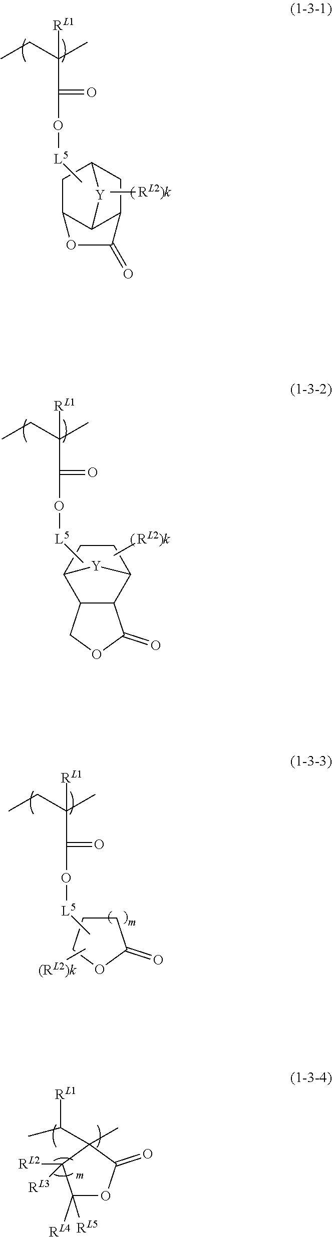

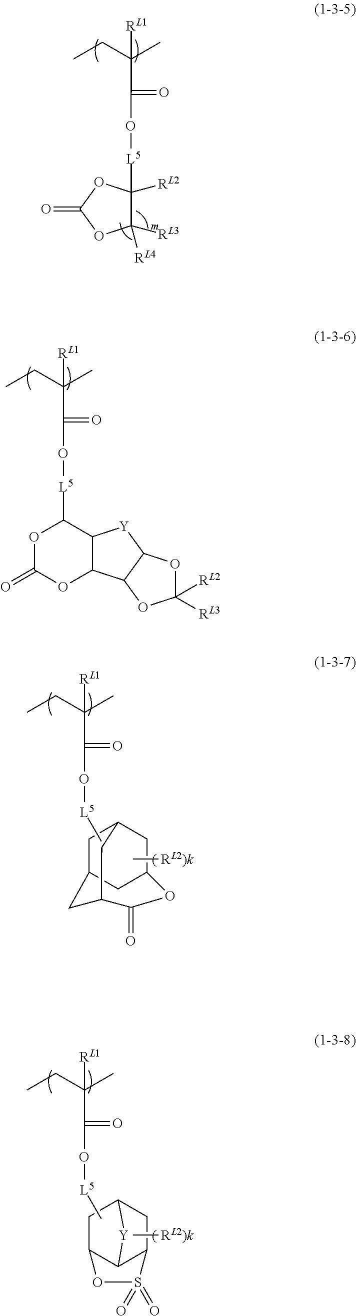

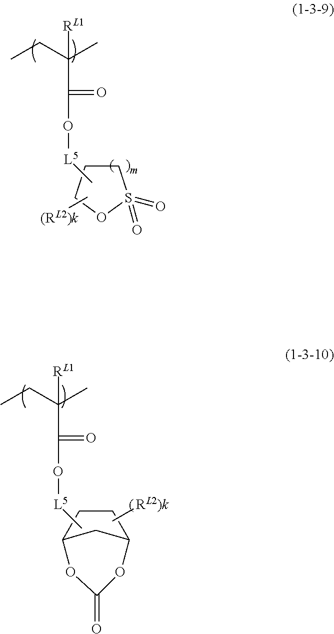

In the formulas, R^{L1} is a hydrogen atom, a fluorine atom, a methyl group, or a trifluoromethyl group. R^{L2} to R^{L5} are each independently a hydrogen atom, an alkyl group having 1 to 4 carbon atoms, a cyano group, a trifluoromethyl group, a methoxy group, a methoxycarbonyl group, a hydroxy group, a hydroxymethyl group, or a dimethylamino group. R^{L4} and R^{L5} may be combined with each other and constitute a divalent alicyclic group having 3 to 8 carbon atoms together with the carbon atom to which they are bonded. L² is a single bond or a divalent linking group. Y is an oxygen atom or a methylene group. k is an integer of 0 to 3. m is an integer of 1 to 3.

The divalent alicyclic group having 3 to 8 carbon atoms composed of the R^{L4} and the R^{L5} combined together as well as the carbon atoms to which the R^{L4} and the R^{L5} are bonded is not particularly limited as long as it is a group formed by removing two hydrogen atoms from the same carbon atom contained in a carbon ring of a monocyclic or polycyclic alicyclic hydrocarbon having the aforementioned number of carbon atoms. The group may be either a monocyclic hydrocarbon group or a polycyclic hydrocarbon group, and the polycyclic hydrocarbon group may be either a bridged alicyclic hydrocarbon group or a fused alicyclic hydrocarbon group, and may be either a saturated hydrocarbon group or an unsaturated hydrocarbon group. The condensed alicyclic hydrocarbon group refers to a polycyclic alicyclic hydrocarbon group that contains a plurality of alicyclic rings sharing a side (bond between two adjacent carbon atoms). One or more hydrogen atoms on this alicyclic group may be substituted with a hydroxy group.

Examples of the divalent linking group represented by L⁵ include a divalent linear or branched hydrocarbon group having 1 to 10 carbon atoms, a divalent alicyclic hydrocarbon group having 4 to 12 carbon atoms, and a group composed of one or more among these hydrocarbon groups and at least one group among —CO—, —O—, —NH—, and —S.

Among these examples, the structural unit (1-3) is preferably a structural unit containing a lactone structure, more preferably a structural unit containing a norbornane lactone structure, and still more preferably a structural unit derived from norbornane lactone-yl (meth)acrylate.

When the polymer [B] has the structural unit (1-3), the lower limit of the content ratio of the structural unit (1-3) accounting for among all structural units constituting the polymer [B](when there are a plurality of types of the structural unit (1-3), the total content ratio is taken) is preferably 30 mol %, more preferably 40 mol %, and still more preferably 45 mol %. The upper limit of the content ratio is preferably 80 mol %, more preferably 70 mol %, and still more preferably 65 mol %.

The lower limit of the weight average molecular weight of the polymer [B] is preferably 500, more preferably 1000, still more preferably 1500, and particularly preferably 2000. The upper limit of the molecular weight is preferably 20000, more preferably 18000, still more preferably 15000, and particularly preferably 12000. The weight average molecular weight is measured as described in EXAMPLES.

The lower limit of the content of the polymer [B] based on 1.0 parts by mass of the compound [A] is preferably 0.00001 parts by mass, more preferably 0.0001 parts by mass, still more preferably 0.0005 parts by mass, and particularly preferably 0.001 parts by mass. The upper limit of the content is preferably 5.0 parts by mass, more preferably 1.0 parts by mass, still more preferably 0.1 parts by mass, and particularly preferably 0.05 parts by mass.

### [Method for Synthesizing Polymer [B]]

The polymer [B] can be synthesized by performing addition polymerization such as radical polymerization or ion polymerization depending on the type of the monomer. For example, when the polymer [A] is synthesized by radical polymerization, the polymer can be synthesized by polymerizing monomers which will afford respective structural units using a radical polymerization initiator of the like in an appropriate solvent.

Examples of the radical polymerization initiator include azo radical initiators, such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile) and dimethyl 2,2′-azobis(isobutyrate); and peroxide radical initiators, such as benzoyl peroxide, t-butyl hydroperoxide and cumene hydroperoxide. These radical initiators may be used singly, or two or more of them may be used in combination.

As the solvent to be used for the polymerization, the solvent [C] described later can be suitably employed. The solvents to be used for the polymerization may be used singly, or two or more solvents may be used in combination.

The reaction temperature in the polymerization is usually 40° C. to 150° C., and preferably 50° C. to 120° C. The reaction time is usually 1 hour to 48 hours, and preferably 1 hour to 24 hours.

### <Solvent [C]>

Examples of the solvent [C] include alcohol-based solvents, ketone-based solvents, ether-based solvents, ester-based solvents, nitrogen-containing solvents, and water. The solvent [C] may be used singly or two or more types thereof may be used in combination.

Examples of alcohol solvents include monoalcohol solvents such as methanol, ethanol, n-propanol, iso-propanol, n-butanol and iso-butanol, polyhydric alcohol solvents such as ethylene glycol, 1,2-propylene glycol, diethylene glycol and dipropylene glycol.

Examples of ketone solvents include acetone, methyl ethyl ketone, methyl-n-propyl ketone, methyl-iso-butyl ketone, cyclohexanone and the like.

Examples of ether solvents include ethyl ether, iso-propyl ether, ethylene glycol dibutyl ether, diethylene glycol monomethyl ether, diethylene glycol monoethyl ether, diethylene glycol diethyl ether, propylene glycol monomethyl ether, propylene glycol monoethyl ether, propylene glycol monopropyl ether, tetrahydrofuran and the like.

Examples of ester solvents include ethyl acetate, γ-butyrolactone, n-butyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate, dipropylene glycol monoethyl ether acetate, ethyl propionate, n-butyl propionate, methyl lactate, ethyl lactate and the like.

Examples of nitrogen-containing solvents include N,N-dimethylformamide, N,N-dimethylacetamide, N-methylpyrrolidone, and the like.

Among these, ether-based solvents, ester-based solvents, or water are preferable, and ether-based solvents or ester-based solvents having a glycol structure, or water are more preferable because of their excellent film-forming properties.

Examples of ether solvents and ester solvents having a glycol structure include propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate and the like. Among these, propylene glycol monomethyl ether acetate or propylene glycol monoethyl ether is preferable.

The content ratio of the ether-based solvent having a glycol structure and the ester-based solvent in the solvent [B] is preferably 20% by mass or more, more preferably 60% by mass or more, still more preferably 90% by mass or more, and particularly preferably 100% by mass.

The lower limit of the content ratio of the solvent [C] in the silicon-containing composition is preferably 80% by mass, more preferably 85% by mass, still more preferably 90% by mass, and particularly preferably 95% by mass. The upper limit of the content ratio is preferably 99.9% by mass, and more preferably 99% by mass.

### <Other Optional Components>

Examples of other optional components include acid generators, basic compounds (including base generators), ortho esters, radical generators, surfactants, colloidal silica, colloidal alumina, and organic polymers. The other optional components may be used singly or two or more kinds thereof may be used in combination.

### (Acid Generator)

The acid generator is a component that generates an acid through exposure to light or heating. When the silicon-containing composition contains an acid generator, the condensation reaction of the compound [A] can be promoted even at a relatively low temperature (including normal temperature).

Examples of the acid generator that generates an acid through exposure to light (hereinafter also referred to as “photo-acid generator”) include the acid generators described in paragraphs [xxxx] to[xxxx] in JP-A-2004-168748, and triphenylsulfonium trifluoromethanesulfonate.

Examples of the acid generator that generates an acid through heating (hereinafter also referred to as “thermal acid generator”) include onium salt-based acid generators recited as examples of photo-acid generators in the above-cited Patent Document, 2,4,4,6-tetrabromocyclohexadienone, benzoin tosylate, 2-nitrobenzyl tosylate, and alkyl sulfonates.

When the silicon-containing composition comprises an acid generator, the lower limit of the content of the acid generator is preferably 0.001 parts by mass, and more preferably 0.01 parts by mass based on 100 parts by mass of the compound [A]. The upper limit of the content of the acid generator is preferably 5 parts by mass, and more preferably 1 part by mass based on 100 parts by mass of the compound [A].

### (Basic Compound)

The basic compound promotes a curing reaction of the silicon-containing composition, and as a result, enhance the strength or the like of a film to be formed. In addition, the basic compound improves the peelability of the film with an acidic solution. Examples of the basic compound include a compound having a basic amino group, and a base generator that generates a compound having a basic amino group by the action of an acid or the action of heat. Examples of the compound having a basic amino group include amine compounds. Examples of the base generator include an amide group-containing compound, a urea compound, and a nitrogen-containing heterocyclic compound. Examples of the amine compound, the amide group-containing compound, the urea compound, and the nitrogen-containing heterocyclic compound include compounds described in paragraphs [xxxx] to[xxxx] of JP-A-2016-27370.

When the silicon-containing composition comprises a basic compound, the lower limit of the content of the basic compound is preferably 0.001 parts by mass, and more preferably 0.01 parts by mass, based on 100 parts by mass of the compound [A]. The upper limit of the content is preferably 5 parts by mass, and more preferably 1 part by mass.

### (Ortho Ester)

The ortho ester is an ester form of an orthocarboxylic acid. The ortho ester reacts with water to afford a carboxylate ester or the like. Examples of the ortho ester include orthoformate esters such as methyl orthoformate, ethyl orthoformate, and propyl orthoformate, orthoacetate esters such as methyl orthoacetate, ethyl orthoacetate, and propyl orthoacetate, and orthopropionate esters such as methyl orthopropionate, ethyl orthopropionate, and propyl orthopropionate. Among them, an orthoformate is preferable, and trimethyl orthoformate is more preferable.

When the silicon-containing composition comprises an ortho ester, the lower limit of the content of the ortho ester is preferably 0.1 parts by mass, more preferably 0.5 parts by mass, and still more preferably 1 part by mass, based on 100 parts by mass of the compound [A]. The upper limit of the content is preferably 10% by mass, more preferably 6% by mass, and still more preferably 4% by mass.

### <Method for Preparing Silicon-Containing Composition>

The method for preparing the silicon-containing composition is not particularly limited, and for example, the composition can be prepared by mixing a solution of the compound [A], the polymer [B], the solvent [C], and other optional components which are used as necessary in a prescribed ratio, and then filtering the resulting mixed solution through a filter having a pore size of 0.2 μm or less.

Hereinbelow, each of the steps of the method for manufacturing a semiconductor substrate will be described with reference to a case where the method includes the organic underlayer film forming step before the silicon-containing film forming step and the silicon-containing film pattern forming step, the etching step, and the removing step after the developing step.

### [Organic Underlayer Film Forming Step]

In this step, an organic underlayer film is formed directly or indirectly on the substrate before the silicon-containing film forming step. This step is an arbitrary step. Through this step, an organic underlayer film is formed directly or indirectly on the substrate.

The organic underlayer film can be formed by applying a composition for forming an organic underlayer film. The method of forming the organic underlayer film by applying the composition for forming an organic underlayer film may be, for example, a method in which a coating film formed by directly or indirectly applying the composition for forming an organic underlayer film to a substrate is cured by heating or exposure. As the composition for forming an organic underlayer film, for example, “HM8006” manufactured by JSR Corporation can be used. Various conditions for heating or exposure can be appropriately determined according to the type of the composition for forming an organic underlayer film to be used.

Examples of a case where an organic underlayer film is indirectly formed on a substrate include a case where an organic underlayer film is formed on a low dielectric insulating film formed on a substrate.

### [Application Step (I)]

In this step, the silicon-containing composition is directly or indirectly applied to the substrate. By this step, a coating film of the composition is formed directly or indirectly on the substrate, and the coating film is usually cured by heating to form a silicon-containing film as a resist underlayer film.

Examples of substrates include insulating films such as silicon oxide, silicon nitride, silicon oxynitride and polysiloxane, and resin substrates. Also, the substrate may be a substrate having patterning such as a wiring groove (trench), a plug groove (vias) and the like.

The method of applying the silicon-containing composition is not particularly limited, and examples thereof include a spin coating method.

Examples of the case of indirectly applying the silicon-containing composition to the substrate include, for example, the case of applying the silicon-containing composition onto another film formed on the substrate. Other films formed on the substrate include, for example, an organic underlayer film which is formed by the organic underlayer film forming step described above, an antireflection film, a low dielectric insulating film, and the like.

When the coating film is heated, the atmosphere is not particularly limited, and examples thereof include air atmosphere, nitrogen atmosphere, and the like. Heating of the coating film is usually performed in the air atmosphere. Various conditions such as the heating temperature and the heating time when the coating film is heated can be appropriately determined. The lower limit of the heating temperature is preferably 90° C., more preferably 150° C., and even more preferably 200° C. The upper limit of the heating temperature is preferably 550° C., more preferably 450° C., and even more preferably 300° C. The lower limit of the heating time is preferably 15 seconds, more preferably 30 seconds. The upper limit of the heating time is preferably 1,200 seconds, more preferably 600 seconds.

When the silicon-containing composition contains an acid generator, and the acid generator is a radiation-sensitive acid generator, the formation of the silicon-containing film can be accelerated by combining heating and exposure. Radiation used for exposure includes, for example, the same radiation as exemplified in the exposing step described later.

The lower limit of the average thickness of the silicon-containing film formed by this step is preferably 1 nm, more preferably 3 nm, and even more preferably 5 nm. The upper limit of the average thickness is preferably 500 nm, more preferably 300 nm, and even more preferably 200 nm. The method for measuring the average thickness of the silicon-containing film is described in Examples.

### [Application Step (II)]

In this step, a composition for forming a resist film is applied to a silicon-containing film formed by applying a silicon-containing composition. Through this step, a resist film is formed directly or indirectly on the silicon-containing film.

The method of applying the composition for forming a resist film is not particularly limited, and examples thereof include a spin coating method.

To explain this step in more detail, for example, after applying a composition for forming a resist film so that the formed resist film has a predetermined thickness, pre-baking (hereinafter also referred to as “PB”) is performed to volatilize the solvent to form a resist film.

The PB temperature and PB time can be appropriately determined according to the type of resist film forming composition used. The lower limit of the PB temperature is preferably 30° C., more preferably 50° C. The upper limit of the PB temperature is preferably 200° C., more preferably 150° C. The lower limit of the PB time is preferably 10 seconds, more preferably 30 seconds. The upper limit of the PB time is preferably 600 seconds, more preferably 300 seconds.

As the composition for forming a resist film used in this step, a so-called positive-type composition for forming a resist film for alkali development is preferably used. Such a composition for forming a resist film is preferably a positive-type composition for forming a resist film containing, for example, a resin having an acid-dissociable group and a radiation-sensitive acid generator and intended for exposure to ArF excimer laser light (for ArF exposure) or exposure to extreme ultraviolet (for EUV exposure).

### [Exposing Step]

In this step, the resist film formed by the resist film forming step is exposed to radiation. This step causes a difference in solubility in an alkaline solution, which is a developer, between an exposed portion and an unexposed portion of the resist film. More specifically, the solubility of the exposed portion of the resist film to an alkaline solution increases.

The radiation used for exposure can be appropriately selected according to the type of a composition for forming a resist film used. Examples thereof include electromagnetic waves such as visible light, ultraviolet rays, far ultraviolet rays, X-rays and γ-rays, and particle beams such as electron beams, molecular beams and ion beams. Among these, far ultraviolet rays are preferable, and KrF excimer laser light (wavelength 248 nm), ArF excimer laser light (wavelength 193 nm), F₂ excimer laser light (wavelength 157 nm), Kr₂ excimer laser light (wavelength 147 nm), ArKr excimer laser light (wavelength of 134 nm) or extreme ultraviolet rays (wavelength of 13.5 nm, etc., also referred to as “EUV”) are more preferred, and ArF excimer laser light or EUV is even more preferred. Also, the exposure conditions can be appropriately determined according to the type of the composition for forming a resist film to be used.

In addition, in this step, post-exposure bake (hereinafter also referred to as “PEB”) can be performed in order to improve the performance of the resist film such as resolution, pattern profile, developability, etc. after the exposure. The PEB temperature and PEB time can be appropriately determined according to the type of composition for forming a resist film used. The lower limit of the PEB temperature is preferably 50° C., more preferably 70° C. The upper limit of the PEB temperature is preferably 200° C., more preferably 150° C. The lower limit of the PEB time is preferably 10 seconds, more preferably 30 seconds. The upper limit of the PEB time is preferably 600 seconds, more preferably 300 seconds.

### [Developing Step]

In this step, at least the exposed resist film is developed. The development of the exposed resist film is preferably alkali development. Due to the above exposing step, the solubility in the alkaline solution, which is the developer, differs between the exposed area and the unexposed area in the resist film. A resist pattern is formed by removing the exposed portion, which is relatively soluble in an alkaline solution, by carrying out alkali development.

The developer used in alkaline development is not particularly limited, and known developers can be used. Examples of developer for alkaline development include an alkaline aqueous solution containing at least one of dissolved alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, and the like. Among these, a TMAH aqueous solution is preferable, and a 2.38% by mass TMAH aqueous solution is more preferable.

Examples of a developer used for organic solvent development include the same developer as those exemplified as the solvent for the composition described above.

In this step, washing and/or drying may be performed after the development.

### [Silicon-Containing Film Pattern Forming Step]

In this step, the silicon-containing film is etched using the resist pattern as a mask to form a silicon-containing film pattern.

The above etching may be dry etching or wet etching, but dry etching is preferred.

Dry etching can be performed using, for example, a known dry etching apparatus. The etching gas used for dry etching can be appropriately selected according to the elemental composition of the silicon-containing film to be etched, and for example, fluorine-based gases such as CHF₃, CF₄, C₂F₆, C₃F₃ and SF₆, chlorine-based gases such as Cl₂ and BCl₃, oxygen-based gases such as O₂, O₃ and H₂O, reducing gases such as H₂, CO, CO₂, CH₄, C₂H₂, C₂H₄, C₂H₆, C₃H₄, C₃H₆, C₃H₈, HF, HI, HBr, HCl, NO and NH₃, and inert gases such as He, N₂ and Ar are used. These gases can also be mixed and used. For dry etching of a silicon-containing film, a fluorine-based gas is usually used, and a mixture of a fluorine-based gas, an oxygen-based gas and an inert gas is preferably used.

### [Etching Step]

In this step, etching is performed using the silicon-containing film pattern as a mask. More specifically, etching is performed one or more times using as a mask the pattern formed in the silicon-containing film obtained in the silicon-containing film pattern forming step to obtain a patterned substrate.

When an organic underlayer film is formed on the substrate, the organic underlayer film is etched using the silicon-containing film pattern as a mask to form a pattern of the organic underlayer film, and then the substrate is etched using this organic underlayer film pattern as a mask. Thus, a pattern is formed on the substrate.

The above etching may be dry etching or wet etching, but dry etching is preferred.

Dry etching for forming a pattern on the organic underlayer film can be performed using a known dry etching apparatus. The etching gas used for dry etching can be appropriately selected depending on the elemental composition of the silicon-containing film and the organic underlayer film to be etched. As the etching gas, the gas for etching the silicon-containing film described above can be suitably used, and these gases can also be mixed and used. An oxygen-based gas is usually used for dry etching of the organic underlayer film using the silicon-containing film pattern as a mask.

Dry etching for forming a pattern on the substrate using the organic underlayer film pattern as a mask can be performed using a known dry etching apparatus. The etching gas used for dry etching can be appropriately selected depending on the elemental composition of the organic underlayer film and the substrate to be etched, and the like. For example, etching gases similar to those exemplified as the etching gas used for the dry etching of the organic underlayer film may be used. Etching may be performed a plurality of times with different etching gases. After the etching step, if the silicon-containing film remains on the substrate, or on the resist underlayer pattern, etc., the silicon-containing film can be removed by performing the removing step described below.

### [Removing Step]

In this step, the silicon-containing film pattern is removed with a basic liquid. This step removes the silicon-containing film from the substrate. Also, the silicon-containing film residue after etching can be removed.

The basic liquid is not particularly limited as long as it is a basic solution containing a basic compound. Examples of basic compounds include sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, choline, 1,8-diazabicyclo[5.4.0]-7-undecene, 1,5-diazabicyclo[4.3.0]-5-nonene and the like. Among these, ammonia is preferable from the viewpoint of avoiding damage to the substrate.

From the viewpoint of further improving the removability of the silicon-containing film, the basic liquid is preferably a liquid containing a basic compound and water, or a liquid containing a basic compound, hydrogen peroxide and water.

The method for removing the silicon-containing film is not particularly limited as long as it is a method that allows the silicon-containing film and the basic liquid to come into contact with each other. Examples thereof include a method of immersing a substrate in a basic liquid, a method of spraying a basic liquid, a method of applying a basic liquid, and the like.

The temperature, time, and other conditions for removing the silicon-containing film are not particularly limited, and can be appropriately determined according to the film thickness of the silicon-containing film, the type of basic liquid used, and the like. The lower limit of the temperature is preferably 20° C., more preferably 40° C., and even more preferably 50° C. The upper limit of the temperature is preferably 300° C., more preferably 100° C. The lower limit of the time is preferably 5 seconds, more preferably 30 seconds. The upper limit of the time is preferably 10 minutes, more preferably 180 seconds.

In this step, washing and/or drying may be performed after removing the silicon-containing film.

### EXAMPLES

Hereinafter, Examples are described. The following Examples merely illustrate typical Examples of the present invention, and the Examples should not be construed to narrow the scope of the present invention.

In the present Examples, the weight-average molecular weight (Mw) of the compound (a) as an intermediate, the compound [A] and the polymer [B], the concentration of a solution of the compound [A], and the average thickness of a film were measured by the following methods.

### [Weight-Average Molecular Weight (Mw)]

The weight-average molecular weight (Mw) of compound (a-1) to compound (a-4) as the compound [a], the compound [A] and the polymer [B] was measured by gel permeation chromatography (GPC) using GPC columns, available from Tosoh Corporation (“G2000HXL”×2, “G3000HXL”×1, and “G4000HXL”×1) under the following conditions.
Eluant: tetrahydrofuran (manufactured by Wako Pure Chemical Industries, Ltd.)
Flow rate: 1.0 mL/min
Sample concentration: 1.0% by mass
Sample injection amount: 100 μL
Column temperature: 40° C.
Detector: differential refractometer
Standard substance: monodisperse polystyrene

### [Concentration of Solution of Compound [A]]

The concentration (% by mass) of a solution of the compound [A] was calculated by firing 0.5 g of the solution of the compound [A] at 250° C. for 30 minutes, measuring a mass of a residue thus obtained, and dividing the mass of the residue by the mass of the solution of the compound [A].

### [Average Thickness of Film]

The average thickness of the film was measured by using a spectroscopic ellipsometer (“M2000D”, available from J. A. WOOLLAM CO.). More specifically, thicknesses of the film formed on a 12-inch silicon wafer were measured at optional nine points located at an interval of 5 cm including the center of the film, and the average value of the film thicknesses was calculated, and taken as the average thickness.

<Synthesis of Compounds (a-1) to (a-4)>

The monomers used for synthesis in Synthesis Examples 1-1 to 1-4 (hereinafter also referred to as “monomers (H-1), (S-1) to (S-4)”) are shown below.

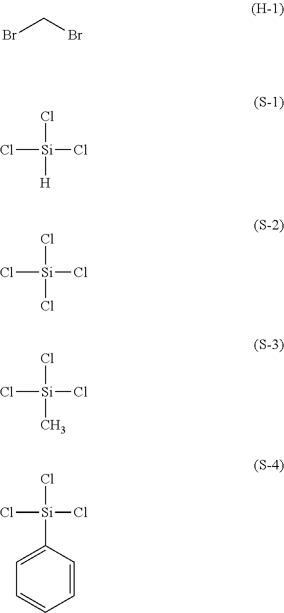

### [Synthesis Example 1-1](Synthesis of Compound (a-1))

To a reaction vessel purged with nitrogen, 5.83 g of magnesium and 11.12 g of tetrahydrofuran were added, and the mixture was stirred at 20° C. Next, 17.38 g of monomer (H-1), 23.2 g of monomer (S-1) (molar ratio: 50/50 (mol %)) were dissolved in 111.15 g of tetrahydrofuran to prepare a monomer solution. The temperature in the reaction vessel was adjusted to 20° C., and the monomer solution was added dropwise thereto over 1 hour with stirring. A time point of completion of the dropwise addition was taken as a start time of a reaction, and the mixture was stirred at 40° C. for 1 hour and then at 60° C. for 3 hours. Then 66.69 g of tetrahydrofuran was added, and the mixture was cooled to 10° C. or lower, affording a polymerization reaction liquid. Subsequently, 30.36 g of triethylamine was added to the polymerization reaction liquid, and then 9.61 g of methanol was added dropwise thereto over 10 minutes with stirring. A time point of completion of the dropwise addition was taken as a start time of a reaction, and the mixture was stirred at 20° C. for 1 hour. Then the reaction liquid was charged into 220 g of diisopropyl ether, and the precipitated salt was filtered off. Next, tetrahydrofuran, diisopropyl ether, triethylamine, and methanol in the filtrate were removed using an evaporator. 50 g of diisopropyl ether was added to the residue obtained, the precipitated salt was filtered off, and diisopropyl ether was added to the filtrate, affording compound (a-1) having a concentration of 12% by mass. The Mw of compound (a-1) was 900.

### [Synthesis Examples 1-2 to 1-4](Synthesis of Compounds (a-2) to (a-4))

Diisopropyl ether solutions of compounds (a-2) to (a-4) were obtained in the same manner as in Synthesis Example 1-1 except that the monomers of the types and use amounts shown in the following Table 1 were used, respectively. The Mw of the compounds (a) obtained is also disclosed in Table 1. “-” in Table 1 indicates that the corresponding monomer was not used.

TABLE 1

| | | | | | | | Concen- | |
|---|---|---|---|---|---|---|---|---|
| | Com- | Charged amount of | | | | | tration | |
| | pound | each monomer (mol %) | | | | | (% by | |
| | (a) | H-1 | S-1 | S-2 | S-3 | S-4 | mass) | Mw |
| Synthesis | a-1 | 50 | 50 | — | — | — | 12 | 900 |
| Example 1-1 | | | | | | | | |
| Synthesis | a-2 | 50 | 25 | 25 | — | — | 12 | 1,000 |
| Example 1-2 | | | | | | | | |
| Synthesis | a-3 | 50 | 35 | — | 15 | — | 12 | 800 |
| Example 1-3 | | | | | | | | |
| Synthesis | a-4 | 50 | 35 | — | — | 15 | 12 | 700 |
| Example 1-4 | | | | | | | | |

### <Synthesis of Compound [A]>

The monomers (hereinafter also referred to as “monomers (M-1) to (M-4)”) used for synthesis in Synthesis Examples 2-1 to 2-7 are shown below. In addition, in the following Synthesis Examples 2-1 to 2-7, mol % means a value taken when the total number of moles of silicon atoms in the compounds (a-1) to (a-4) used and the monomers (M-1) to (M-4) used is 100 mol %.

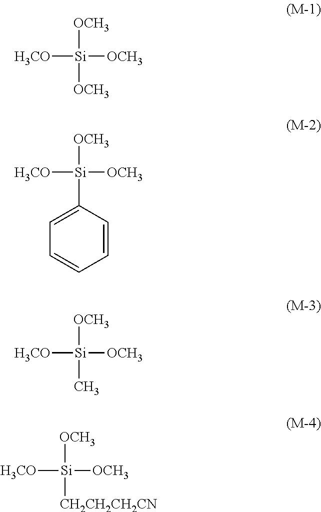

### [Synthesis Example 2-1](Synthesis of Compound (A-1))

A reaction vessel was charged with 23.87 g of the diisopropyl ether solution of compound (a-1) obtained in Synthesis Example 1-1 and 24.29 g of acetone. The temperature in the reaction vessel was adjusted to 30° C., and 1.84 g of a 3.2% by mass aqueous solution of oxalic acid was added dropwise thereto over 20 minutes with stirring. A time point of completion of the dropwise addition was taken as a start time of a reaction, and the mixture was stirred at 40° C. for 4 hours. Then the inside of the reaction vessel was cooled to 30° C. or lower. Next, 25.0 g of diisopropyl ether and 150 g of water were added to this reaction vessel, and liquid separation extraction was performed. Thereafter, to the obtained organic layer was added 75 g of propylene glycol monomethyl ether acetate, and then water, acetone, diisopropyl ether, alcohols produced by the reaction, and excessive propylene glycol monomethyl ether acetate were removed using an evaporator. Subsequently, 5.0 g of trimethyl orthoformate as a dehydrating agent was added to the obtained solution, and the mixture was stirred at 40° C. for 1 hour, and then the inside of the reaction vessel was cooled to 30° C. or lower. Alcohols generated through the reaction, esters, trimethyl orthoformate, and excess propylene glycol monomethyl ether acetate were removed using the evaporator, affording a 5% by mass solution of compound (A-1) as the compound [A]. The Mw of compound (A-1) was 2,200.

### [Synthesis Examples 2-2 to 2-7]<Synthesis of Compounds (A-2) to (A-7)>

Propylene glycol monomethyl ether acetate or propylene glycol monoethyl ether solutions of compounds (A-2) to (A-7) as the compound [A] were obtained in the same manner as in Synthesis Example 2-1 except that the compounds and the monomers of the types and amounts shown in the following Table 2 were used. “-” in the columns of monomer in the following Table 2 indicates that the corresponding monomer was not used. The concentration (% by mass) of the obtained solution of the compound [A] and the Mw of the compound [A] are also shown in Table 2.

TABLE 2

| | | | | | | | | Con- | |
|---|---|---|---|---|---|---|---|---|---|
| | | Charged amount of compound | | | | | | cen- | |
| | Com- | and each monomer (Si mol %) | | | | | | tration | |
| | pound | Com- | | | | | | (% by | |
| | [A] | pound | | M-1 | M-2 | M-3 | M-4 | mass) | Mw |
| Synthesis | A-1 | a-1 | 100 | — | — | — | — | 5 | 2200 |
| Example | | | | | | | | | |
| 2-1 | | | | | | | | | |
| Synthesis | A-2 | a-2 | 100 | — | — | — | — | 5 | 3000 |
| Example | | | | | | | | | |
| 2-2 | | | | | | | | | |
| Synthesis | A-3 | a-3 | 100 | — | — | — | — | 5 | 2000 |
| Example | | | | | | | | | |
| 2-3 | | | | | | | | | |
| Synthesis | A-4 | a-4 | 100 | — | — | — | — | 5 | 1800 |
| Example | | | | | | | | | |
| 2-4 | | | | | | | | | |
| Synthesis | A-5 | — | — | 90 | 10 | — | — | 5 | 2350 |
| Example | | | | | | | | | |
| 2-5 | | | | | | | | | |
| Synthesis | A-6 | — | — | 50 | — | 50 | — | 5 | 2500 |
| Example | | | | | | | | | |
| 2-6 | | | | | | | | | |
| Synthesis | A-7 | — | — | 70 | 20 | — | 10 | 5 | 2400 |
| Example | | | | | | | | | |
| 2-7 | | | | | | | | | |

### <Synthesis of Polymer [B]>

As the polymer [B], polymers represented by formulas (B-1) to (B-6) (hereinafter also referred to as “polymers (B-1) to (B-6)”) were synthesized by the following procedures.

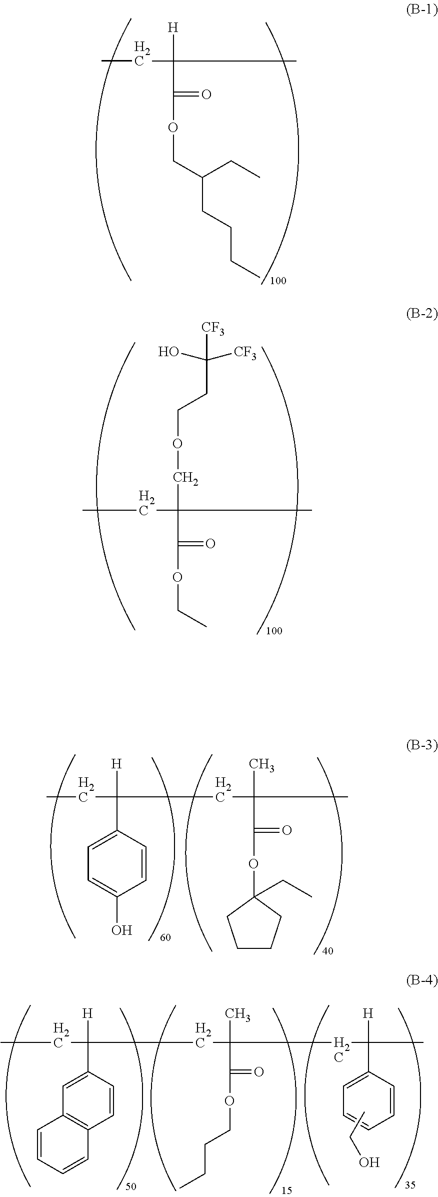

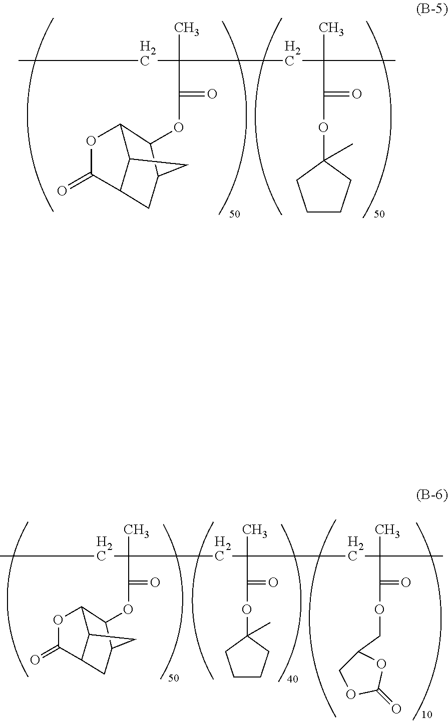

In the formulas (B-1) to (B-6), the number attached to each structural unit indicates the content ratio (mol %) of the structural unit.

### [Synthesis Example 3-1](Synthesis of Polymer (B-1))

2-Ethylhexyl acrylate (43.0 g) was dissolved in 130 g of methyl isobutyl ketone, and 19.6 g of dimethyl 2,2′-azobis(isobutyrate) was added to prepare a monomer solution. Under a nitrogen atmosphere, 70 g of methyl isobutyl ketone was placed in a reaction vessel and heated to 80° C., and the monomer solution was added dropwise over 3 hours with stirring. The start of the dropwise addition was regarded as the start time of a polymerization reaction, the polymerization reaction was performed for 6 hours with stirring, and then the resulting mixture was cooled to 30° C. or lower. To the resulting reaction solution was added 300 g of propylene glycol monomethyl ether acetate, and methyl isobutyl ketone was removed by concentration under reduced pressure, affording a propylene glycol monomethyl ether acetate solution of polymer (B-1). The Mw of the polymer (B-1) was 10,000.

### [Synthesis Examples 3-2 to 3-6](Synthesis of Polymers (B-2) to (B-6))

Propylene glycol monomethyl ether acetate solutions of the polymers (B-2) to (B-6) were obtained in the same manner as in Synthesis Example 3-1 except that monomers capable of affording the structural units in the content ratios (mol %) shown in the formulas (B-2) to (B-6) were used. The Mw of polymer (B-2) was 3,800, the Mw of polymer (B-3) was 4,000, the Mw of polymer (B-4) was 4,300, the Mw of polymer (B-5) was 4,500, and the Mw of polymer (B-6) was 4,100.

### <Preparation of Silicon-Containing Composition>

The components used for the preparation of silicon-containing compositions are shown below. In the following Examples 1-1 to 1-23 and Comparative Examples 1-1 and 1-9, unless otherwise specified, parts by mass represents a value taken when the total mass of components used is 100 parts by mass.

### [Compound [A]]

A-1 to A-7: Compounds (A-1) to (A-7) synthesized above

### [Polymer [B]]

B-1 to B-6: Polymers (B-1) to (B-6) synthesized above

### [Solvent [C]]

C-1: Propylene glycol monomethyl ether acetate

C-2: Propylene glycol monomethyl ether

C-3: Water

C-4: Propylene glycol monoethyl ether

### [Other Optional Component [D]]

D-1 (Acid generator): Compound represented by formula (D-1)

D-2 (Acid generator): Compound represented by formula (D-2) (in the formula, “Bu” represents an n-butyl group)

D-3 (Acid generator): Compound represented by formula (D-3)

D-4 (Basic compound): Compound represented by formula (D-4)

D-5 (ortho ester): Trimethyl orthoformate

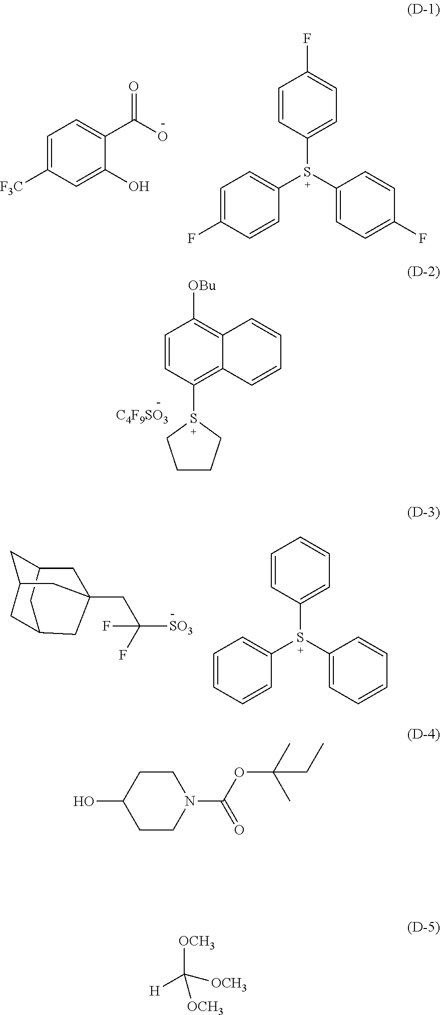

### [Example 1-1](Preparation of Composition (J-1))

Silicon-containing composition (J-1) was prepared by mixing 1.00 parts by mass of (A-1) (excluding the solvent) as the compound [A], 0.03 parts by mass of (B-1) as the polymer [B], 95.96 parts by mass of (C-1) as the solvent [C](including the solvent (C-1) contained in the solution of the compound [A]), 0.01 parts by mass (D-1) and 3.00 parts by mass of (D-5) as other optional components [D], and filtering the resulting solution through a filter having a pore size of 0.2 μm.

### Examples 1-2 to 1-23, Comparative Examples 1-1 to 1-9

(Preparation of Compositions (J-2) to (J-23) and (j-1) to (j-9))

Compositions (J-2) to (J-23) of Examples 1-2 to 1-23 and compositions (j-1) to (j-9) of Comparative Examples 1-1 to 1-9 were prepared in the same manner as in Example 1-1 except that respective components of types and blending amounts shown in the following Table 3 were used. “-” in the following Table 3 indicates that the corresponding component was not used.

### <Evaluation>

Using the compositions prepared as described above, resist pattern collapse inhibition property and film thickness uniformity were evaluated by the following methods. The evaluation results are shown in the following Table 3.

### <Preparation of Resist Composition for EUV Exposure>

Resist composition for EUV exposure (R-1) was prepared by mixing 100 parts by mass of resin (r-1), 20 parts by mass of an acid generator (F-1), 50 mol % of an acid diffusion controlling agent (G-1) with respect to the acid generator (F-1), and 7700 parts by mass of propylene glycol monomethyl ether acetate and 3300 parts by mass of propylene glycol monomethyl ether as solvents, and filtering the mixture through a membrane filter having a pore size of 0.2 μm.

The resin (r-1) was a polymer in which the content ratios of structural units derived from the following monomer (E-1) and monomer (E-2) were 50 mol % and 50 mol %, respectively, and had an Mw of 6,400 and an Mw/Mn of 1.50. As the acid generator (F-1) and the acid diffusion controlling agent (G-1), the following compounds were used.

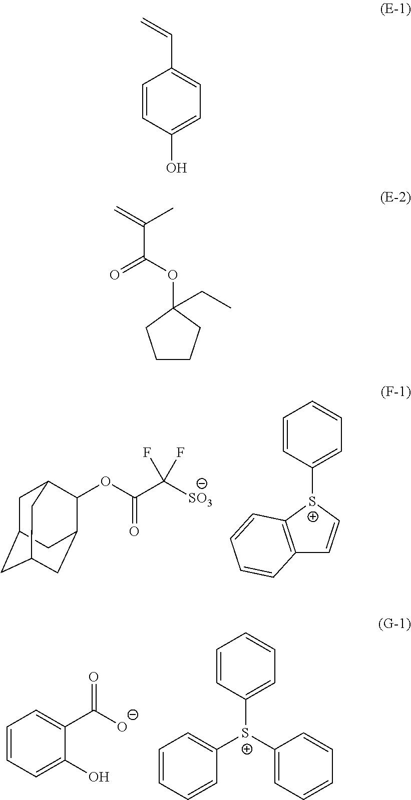

### [Collapse Inhibition Property of Resist Pattern]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Limited), and thereafter heating was conducted at 250° C. for 60 sec to form an organic underlayer film having an average thickness of 100 nm. Each composition prepared as described above was applied on the organic underlayer film, and subjected to heating at 220° C. for 60 sec, followed by cooling at 23° C. for 30 sec to form a silicon-containing film having an average thickness of 20 nm. A resist composition for EUV exposure (R-1) was applied on each silicon-containing film formed as described above, and heating was conducted at 130° C. for 60 sec, followed by cooling at 23° C. for 30 sec to form a resist film having an average thickness of 50 nm. Next, the resist film was irradiated with extreme ultraviolet rays using an EUV scanner (“TWINSCAN NXE:3300B”, available from ASML Co. (NA=0.3; Sigma=0.9; quadrupole illumination, with a 1:1 line and space mask having a line width of 16 nm in terms of a dimension on wafer)). After the irradiation with the extreme ultraviolet rays, the substrate was heated at 110° C. for 60 sec, followed by cooling at 23° C. for 60 sec. Thereafter, development was performed by a paddle method using a 2.38% by mass aqueous tetramethylammonium hydroxide solution (20° C. to 25° C.), followed by washing with water and drying, thereby affording a substrate for evaluation having a resist pattern formed thereon. A scanning electron microscope (“SU8220” available from Hitachi High-Technologies Corporation) was used for length measurement and observation of the resist pattern of the substrate for evaluation. The resist pattern collapse inhibition property was evaluated as “A” (very good) when, in an image (540 nm long, 540 nm wide, 250,000 magnifications) of a 1:1 line-and-space pattern having a line width of 26 nm in the substrate for evaluation, no collapse was confirmed (collapse ratio: 0%); evaluated as “B” (good) when photographs in which collapse was confirmed accounted for 10% or less among the captured images (collapse ratio <10%); evaluated as “C” (poor) when photographs in which collapse was confirmed accounted for 30% or less among the captured images (collapse ratio <30%); and evaluated as “D” (very poor) when photographs in which collapse was confirmed accounted for 50% or less among the captured images (collapse ratio <50%).

### [Evaluation of Film Thickness Uniformity in Wafer]

Each of the silicon-containing compositions prepared as described above was applied to an 8-inch silicon wafer by a spin coating method using a spin coater (“CLEAN TRACK ACT8” available from Tokyo Electron Limited), heated at 250° C. for 60 seconds in the air atmosphere, and then cooled at 23° C. for 30 seconds, thereby forming a silicon-containing film having an average thickness of 10 nm. The substrate with the silicon-containing film formed thereon was evaluated by using a spectroscopic ellipsometer (“M2000D” available from J. A. WOOLLAM CO.). The case where the difference between the film thickness at the wafer center and the film thickness at the wafer edge was less than 0.15 nm was evaluated as “A”, the case where the difference was 0.15 nm or more and less than 0.3 nm was evaluated as “B”, and the case where the difference was 0.3 nm or more was evaluated as “C”.

TABLE 3

| | | | | | | | | Other optional | | Pattern | |
|---|---|---|---|---|---|---|---|---|---|---|---|
| | | Compound [A] | | Polymer [B] | | Solvent [C] | | component [D] | | collapse | |
| | Silicon- | | Blending | | Blending | | Blending | | Blending | inhibition | |
| | containing | | amount | | amount | | amount | | amount | property | |
| | com- | | (parts by | | (parts by | | (parts by | | (parts by | (EUV | Thickness |
| | position | Type | mass) | Type | mass) | Type | mass) | Type | mass) | exposure) | uniformity |
| Example 1-1 | J-1 | A-1 | 1.00 | B-1 | 0.03 | C-1 | 95.96 | D-1/D-5 | 0.01/3.00 | B | B |
| Example 1-2 | J-2 | A-1 | 1.00 | B-1 | 0.01 | C-1 | 95.98 | D-1/D-5 | 0.01/3.00 | B | B |
| Example 1-3 | J-3 | A-1 | 1.00 | B-1 | 0.05 | C-1 | 95.94 | D-1/D-5 | 0.01/3.00 | B | B |
| Example 1-4 | J-4 | A-1 | 1.00 | B-1 | 0.001 | C-1 | 95.989 | D-1/D-5 | 0.01/3.00 | B | B |
| Example 1-5 | J-5 | A-1 | 1.00 | B-1 | 0.005 | C-1 | 95.985 | D-1/D-5 | 0.01/3.00 | B | B |
| Example 1-6 | J-6 | A-1 | 1.00 | B-2 | 0.03 | C-1 | 98.96 | D-1 | 0.01 | B | A |
| Example 1-7 | J-7 | A-1 | 1.00 | B-3 | 0.03 | C-1 | 98.96 | D-1 | 0.01 | A | A |
| Example 1-8 | J-8 | A-1 | 1.00 | B-4 | 0.03 | C-1 | 98.96 | D-1 | 0.01 | B | A |
| Example 1-9 | J-9 | A-1 | 1.00 | B-5 | 0.03 | C-1 | 98.96 | D-1 | 0.01 | A | B |
| Example | J-10 | A-1 | 1.00 | B-6 | 0.03 | C-1 | 98.96 | D-1 | 0.01 | A | B |
| 1-10 | | | | | | | | | | | |
| Example | J-11 | A-1 | 1.00 | B-3 | 0.03 | C-1 | 98.94 | D-2 | 0.03 | A | B |
| 1-11 | | | | | | | | | | | |
| Example | J-12 | A-1 | 1.00 | B-3 | 0.03 | C-1 | 98.97 | — | — | A | B |
| 1-12 | | | | | | | | | | | |
| Example | J-13 | A-1 | 1.00 | B-3 | 0.03 | C-1 | 98.96 | D-1 | 0.01 | A | A |
| 1-13 | | | | | | | | | | | |
| Example | J-14 | A-2 | 1.00 | B-3 | 0.03 | C-1 | 98.96 | D-1 | 0.01 | A | A |
| 1-14 | | | | | | | | | | | |
| Example | J-15 | A-3 | 1.00 | B-3 | 0.03 | C-1 | 98.96 | D-1 | 0.01 | A | B |
| 1-15 | | | | | | | | | | | |
| Example | J-16 | A-4 | 1.00 | B-3 | 0.03 | C-1 | 98.96 | D-1 | 0.01 | A | B |
| 1-16 | | | | | | | | | | | |
| Example | J-17 | A-1 | 1.00 | B-3 | 0.03 | C-1/C-2/ | 28.4/ | D-1 | 0.01 | A | A |
| 1-17 | | | | | | C-3 | 66.46/4.00 | | | | |
| Example | J-18 | A-5 | 1.00 | B-3 | 0.03 | C-1/C-3/ | 9.50/ | — | — | A | A |
| 1-18 | | | | | | C-4 | 4.00/85.47 | | | | |
| Example | J-19 | A-5 | 1.00 | B-3 | 0.03 | C-1/C-3/ | 9.50/ | D-3 | 0.02 | A | A |
| 1-19 | | | | | | C-4 | 4.00/85.45 | | | | |
| Example | J-20 | A-5 | 1.00 | B-3 | 0.03 | C-1/C-3/ | 9.50/ | D-4 | 0.02 | A | A |
| 1-20 | | | | | | C-4 | 4.00/85.45 | | | | |
| Example | J-21 | A-5/A-6 = | 1.00 | B-3 | 0.03 | C-1/C-3/ | 9.50/ | D-4 | 0.02 | A | A |
| 1-21 | | 85/15 | | | | C-4 | 4.00/85.45 | | | | |
| Example | J-22 | A-5/A-6 = | 1.00 | B-3 | 0.03 | C-1/C-3/ | 9.50/ | D-4 | 0.02 | A | A |
| 1-22 | | 70/30 | | | | C-4 | 4.00/85.45 | | | | |
| Example | J-23 | A-7 | 1.00 | B-3 | 0.03 | C-1/C-3 | 98.57/0.4 | — | — | A | A |
| 1-23 | | | | | | | | | | | |
| Comparative | j-1 | A-1 | 1.00 | — | — | C-1 | 98.99 | D-1 | 0.01 | C | C |
| Example 1-1 | | | | | | | | | | | |
| Comparative | j-2 | A-1 | 1.00 | — | — | C-1 | 95.99 | D-1/D-5 | 0.01/3.00 | C | C |
| Example 1-2 | | | | | | | | | | | |
| Comparative | j-3 | A-5 | 1.00 | — | — | C-1/C-2/ | 28.50/ | D-1 | 0.01 | C | A |
| Example 1-3 | | | | | | C-3 | 66.49/4.00 | | | | |
| Comparative | j-4 | A-5 | 1.00 | — | — | C-1/C-3/ | 9.50/ | — | — | D | A |
| Example 1-4 | | | | | | C-4 | 4.00/85.50 | | | | |
| Comparative | j-5 | A-5 | 1.00 | — | — | C-1/C-3/ | 9.50/ | D-3 | 0.02 | D | A |
| Example 1-5 | | | | | | C-4 | 4.00/85.48 | | | | |
| Comparative | j-6 | A-5 | 1.00 | — | — | C-1/C-3/ | 9.50/ | D-4 | 0.02 | D | A |
| Example 1-6 | | | | | | C-4 | 4.00/85.48 | | | | |
| Comparative | j-7 | A-5/A-6 = | 1.00 | — | — | C-1/C-3/ | 9.50/ | D-4 | 0.02 | D | A |
| Example 1-7 | | 85/15 | | | | C-4 | 4.00/85.48 | | | | |
| Comparative | j-8 | A-5/A-6 = | 1.00 | — | — | C-1/C-3/ | 9.50/ | D-4 | 0.02 | D | A |
| Example 1-8 | | 70/30 | | | | C-4 | 4.00/85.48 | | | | |
| Comparative | j-9 | A-7 | 1.00 | — | — | C-1/C-3 | 98.60/0.40 | — | — | D | A |
| Example 1-9 | | | | | | | | | | | |

As is apparent from the results in Table 3, the silicon-containing films formed from the silicon-containing compositions of Examples could exhibit superior pattern collapse inhibition property and film thickness uniformity as compared with the silicon-containing films formed from the compositions of Comparative Examples

According to the method for producing a semiconductor substrate and the silicon-containing composition of the present disclosure, a silicon-containing film superior in pattern collapse inhibition property and film thickness uniformity can be formed. Therefore, these can be suitably used for producing the semiconductor substrate and the like.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for producing a semiconductor substrate, comprising:
applying a silicon-containing composition directly or indirectly to a substrate to form a silicon-containing film;
applying a composition for forming a resist film to the silicon-containing film to form a resist film;
exposing the resist film to radiation; and
developing at least the exposed resist film,
wherein the silicon-containing composition comprises:
a silicon-containing compound;
a polymer comprising a structural unit represented by formula (1); and
a solvent, and
a content of the silicon-containing compound in the silicon-containing composition relative to 100% by mass of components other than the solvent in the silicon-containing composition is from 50% to 99.9% by mass, 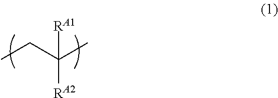
wherein, in the formula (1), R^{A1} is a hydrogen atom or a monovalent organic group having 1 to 20 carbon atoms; and R^{A2} is a monovalent organic group having 1 to 20 carbon atoms.

2. The method according to claim 1, wherein the structural unit represented by formula (1) is at least one structural unit selected from the group consisting of a structural unit represented by formula (1-1) and a structural unit represented by formula (1-2), which is other than the structural unit represented by the formula (1-1), 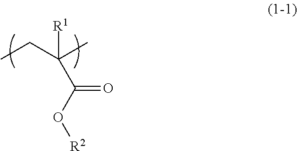
wherein, in the formula (1-1), R¹ is a hydrogen atom or a substituted or unsubstituted monovalent organic group having 1 to 20 carbon atoms; and R² is a monovalent organic group having 1 to 20 carbon atoms, 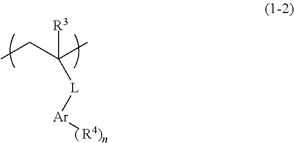
wherein, in the formula (1-2), R³ is a hydrogen atom or a substituted or unsubstituted monovalent hydrocarbon group having 1 to 20 carbon atoms; L is a single bond or a divalent linking group; Ar is a group obtained by removing (n+1) hydrogen atoms from a substituted or unsubstituted aromatic ring having 6 to 20 ring members; R⁴ is a monovalent organic group having 1 to 20 carbon atoms or a hydroxy group; n is an integer of 0 to 8; and when n is 2 or more, the plurality of R⁴s are identical or different.

3. The method according to claim 1, wherein the radiation is an electron beam or extreme ultraviolet rays.

4. A silicon-containing composition for forming a resist underlayer film, the silicon-containing composition comprising:
a silicon-containing compound;
a polymer comprising a structural unit represented by formula (1); and
a solvent,
wherein a content of the silicon-containing compound in the silicon-containing composition relative to 100% by mass of components other than the solvent in the silicon-containing composition is from 50% to 99.9% by mass, 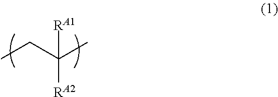
wherein, in the formula (1), R^{A1} is a hydrogen atom or a monovalent organic group having 1 to 20 carbon atoms; and R^{A2} is a monovalent organic group having 1 to 20 carbon atoms.

5. The silicon-containing composition according to claim 4, wherein the structural unit represented by formula (1) is at least one structural unit selected from the group consisting of a structural unit represented by formula (1-1) and a structural unit represented by formula (1-2), which is other than the structural unit represented by the formula (1-1), 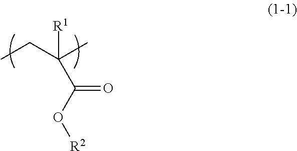
wherein, in the formula (1-1), R¹ is a hydrogen atom or a substituted or unsubstituted monovalent organic group having 1 to 20 carbon atoms; and R² is a monovalent organic group having 1 to 20 carbon atoms, 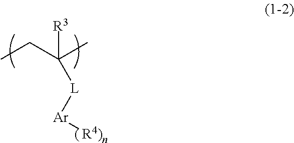
wherein, in the formula (1-2), R³ is a hydrogen atom or a substituted or unsubstituted monovalent hydrocarbon group having 1 to 20 carbon atoms; L is a single bond or a divalent linking group; Ar is a group obtained by removing (n+1) hydrogen atoms from a substituted or unsubstituted aromatic ring having 6 to 20 ring members; R⁴ is a monovalent organic group having 1 to 20 carbon atoms or a hydroxy group; n is an integer of 0 to 8; and when n is 2 or more, the plurality of R⁴s are identical or different.

6. The silicon-containing composition according to claim 5, wherein at least one of R¹, R², R³, and R⁴ has a hydroxy group.

7. The silicon-containing composition according to claim 4, wherein the silicon-containing compound comprises at least one structural unit selected from the group consisting of a structural unit represented by formula (2-1) and a structural unit represented by formula (3-1), 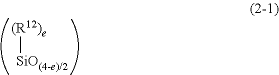
wherein in the formula (2-1), R¹² is a monovalent organic group having 1 to 20 carbon atoms, a hydroxy group, or a halogen atom; e is an integer of 0 to 3; when e is 2 or more, the plurality of R¹²s are identical or different; and 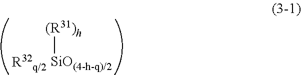
wherein in the formula (3-1), R³¹ is a monovalent organic group having 1 to 20 carbon atoms, a hydroxy group, a hydrogen atom, or a halogen atom; h is 1 or 2; when h is 2, two R³¹s are identical or different from each other; R³² is a substituted or unsubstituted divalent hydrocarbon group having 1 to 20 carbon atoms and bonded to two silicon atoms; q is an integer of 1 to 3; when q is 2 or more, the plurality of R³²s are identical or different from each other; and h+q is 4 or less.

8. The silicon-containing composition according to claim 7, wherein the silicon-containing compound comprises the structural unit represented by the formula (2-1).

9. The silicon-containing composition according to claim 7, wherein the silicon-containing compound comprises the structural unit represented by the formula (3-1).

10. The silicon-containing composition according to claim 4, wherein a content of the polymer in the silicon-containing composition relative to 1.0 parts by mass of the silicon-containing compound is from 0.00001 parts to 5.0 parts by mass.
